(19) United States
(12) Patent Application Publication
(10) Pub. No.: US 2024/0381726 A1
(43) Pub. Date: Nov. 14, 2024

(54) DISPLAY PANEL AND ELECTRONIC DEVICE

(71) Applicants: Chengdu BOE Optoelectronics Technology Co., Ltd., Sichuan (CN); BOE Technology Group Co. Ltd., Beijing (CN)

(72) Inventors: Xiaoxiao WANG, Beijing (CN); Ruoxiang LI, Beijing (CN); Yao HU, Beijing (CN); Shuo LI, Beijing (CN); Zhu WANG, Beijing (CN); Dan GUO, Beijing (CN)

(21) Appl. No.: 18/691,063

(22) PCT Filed: Dec. 30, 2021
(86) PCT No.: PCT/CN2021/143227

§ 371 Date: Mar. 12, 2024

(51) Int. Cl. H10K 59/131; H10K 59/121

(52) U.S. Cl. CPC H10K 59/1315; H10K 59/1213; H10K 59/1216

(57) ABSTRACT

A display panel and an electronic device. The display panel includes a holing area and a display area surrounding the holing area, and the display panel is provided with row lines extending in a first direction, and column lines extending in a second direction; some row lines are separated by the holing area into mutually corresponding first row line sections and second row line sections; some column lines are separated by the holing area into mutually corresponding first column line sections and second column line sections; at least some of the first column line sections are electrically connected to the corresponding second column line sections by means of corresponding transfer lines located in the display area; and/or at least some of the first row line sections are electrically connected to the corresponding second row line sections by means of corresponding transfer lines located in the display area.

### CROSS REFERENCE TO RELATED APPLICATIONS

The present disclosure is the U.S. national phase application of International Application No. PCT/CN2021/143227 filed on Dec. 30, 2021, the content of which is incorporated herein by reference in its entirety for all purposes.

### TECHNICAL FIELD

The present disclosure relates to the field of display technology, in particular to a display panel and an electronic device.

### BACKGROUND

In a full screen product, a display screen can be provided with holes, and photosensitive devices such as cameras and sensors can be installed in the holes.

The information disclosed in the above section is only intended to enhance the understanding of the background of the present disclosure, and thus can include information that does not constitute the prior art already known to those skilled in the art.

### SUMMARY

According to one aspect of the present disclosure, a display panel is provided, including a holing area and a display area surrounding the holing area, wherein the display panel is provided with a row line extending along a first direction and a column line extending along a second direction, and the first direction intersects with the second direction; and wherein a portion of the row line is separated by the holing area into a first row line section and a second row line section corresponding to each other, and a portion of the column line is separated by the holing area into a first column line section and a second column line section corresponding to each other; and wherein at least a portion of the first column line section is electrically connected to the second column line section corresponding thereto through a transfer line corresponding thereto located in the display area; and/or, at least a portion of the first row line section is electrically connected to the second row line section corresponding thereto through a transfer line corresponding thereto located in the display area.

According to some embodiments of the present disclosure, the column line includes a data line for loading driving data, and a portion of the data line is separated by the holing area into a first data line section and a second data line section corresponding to each other; wherein the first data line section is electrically connected to the second data line section corresponding thereto through a column transfer line corresponding thereto located in the display area.

According to some embodiments of the present disclosure, the column transfer line includes a first column transfer line section, a second column transfer line section, and a third column transfer line section that are connected in sequence; wherein the first column transfer line section is electrically connected to the first data line section, and the third column transfer line section is electrically connected to the second data line section.

According to some embodiments of the present disclosure, the first column transfer line section and the third column transfer line section extend along the first direction, and the second column transfer line section extends along the second direction; the holing area has a column central axis extending along the second direction; column transfer lines electrically connected with first data line sections that are located on one side of the column central axis are located on the same side of the column central axis.

According to some embodiments of the present disclosure, the column transfer line includes two portions of column transfer lines respectively located on both sides of the column central axis; ends of the column transfer lines located on the same side of the column central axis are arranged in a straight line along the second direction.

According to some embodiments of the present disclosure, an end of the first column transfer line section away from the second column transfer line section overlaps and is electrically connected with the first data line section corresponding thereto, and an end of the third column transfer line section away from the second column transfer line section overlaps and is electrically connected with the second data line section corresponding thereto.

According to some embodiments of the present disclosure, the column line further includes a driving power line extending along the second direction, and the second column transfer line section overlaps with the driving power line.

According to some embodiments of the present disclosure, the display area is provided with pixel driving circuits arranged in an array, and the pixel driving circuits are arranged in multiple rows of pixel driving circuits and multiple columns of pixel driving circuits; two first column transfer line sections adjacent along the second direction are respectively located in two adjacent rows of pixel driving circuits; two third column transfer line sections adjacent along the second direction are respectively located in two adjacent rows of pixel driving circuits; and two second column transfer line sections adjacent along the first direction are respectively located in two adjacent columns of pixel driving circuits.

According to some embodiments of the present disclosure, the row line includes a scanning line for loading a scanning signal, and a portion of the scanning line is separated by the holing area into a first scanning line section and a second scanning line section corresponding to each other; wherein the first scanning line section is electrically connected to the second scanning line section corresponding thereto through a row transfer line corresponding thereto located in the display area.

According to some embodiments of the present disclosure, at least a portion of the row transfer line is a first row transfer line, the first row transfer line includes a first row transfer line section, a second row transfer line section, and a third row transfer line section that are connected in sequence, the first row transfer line section and the third row transfer line section extend along the second direction, and the second row transfer line section extends along the first direction; wherein the first row transfer line section is electrically connected to the first scanning line section corresponding thereto, and the third row transfer line section is electrically connected to the second scanning line section corresponding thereto.

According to some embodiments of the present disclosure, the first row transfer line section of the first row transfer line is electrically connected to the first scanning line section corresponding thereto at an end of the first row transfer line section, and the third row transfer line section of the first row transfer line is electrically connected to the second scanning line section corresponding thereto at an end of the third row transfer line section.

According to some embodiments of the present disclosure, a portion of the row transfer line is a second row transfer line, the second row transfer line includes a fourth row transfer line section, a first row transfer line section, a second row transfer line section, a third row transfer line section, and a fifth row transfer line section that are connected in sequence, the first row transfer line section and the third row transfer line section extend along the second direction, and the fourth row transfer line section, the second row transfer line section, and the fifth row transfer line section extend along the first direction; and the fourth row transfer line section is electrically connected to the first scanning line section corresponding thereto at an end of the fourth row transfer line section away from the first row transfer line section, and the fifth row transfer line section is electrically connected to the second scanning line section corresponding thereto at an end of the fifth row transfer line section way from the third row transfer line section.

According to some embodiments of the present disclosure, the fourth row transfer line section overlaps with the first scanning line section corresponding thereto, and the fifth row transfer line section overlaps with the second scanning line section corresponding thereto.

According to some embodiments of the present disclosure, the display panel is provided with a driving power line extending along the second direction; and the first row transfer line section and the third row transfer line section respectively overlap with the driving power line.

According to some embodiments of the present disclosure, the holing area has a row central axis extending along the first direction; and row transfer lines corresponding to first scanning line sections that are located on one side of the row central axis are located on the same side of the row central axis.

According to some embodiments of the present disclosure, the row line further includes a reset control line, the reset control line corresponds to the scanning line and is configured for loading a reset control signal, a signal loaded by the reset control line is consistent with a signal loaded by the scanning line corresponding thereto, and a portion of the reset control line is separated by the holing area into a first reset control line section and a second reset control line section corresponding to each other; wherein the first scanning line section and the first reset control line section corresponding thereto are arranged side by side, and are electrically connected to the same first row transfer line section; and the second scanning line section and the second reset control line section corresponding thereto are arranged side by side, and are electrically connected to the same third row transfer line section.

According to some embodiments of the present disclosure, the holing area includes a hole and an enclosing area surrounding the hole; wherein the enclosing area is provided with scanning transfer structures corresponding to the first scanning line section and the second scanning line section one by one; and wherein the first scanning line section and the first reset control line section corresponding thereto are electrically connected to a scanning transfer structure corresponding thereto; and the second scanning line section and the second reset control line section corresponding thereto are electrically connected to a scanning transfer structure corresponding thereto.

According to some embodiments of the present disclosure, the scanning line and the reset control line corresponding thereto are located on the same conductive layer, and the scanning line, the scanning transfer structure, and the row transfer line are located on different conductive layers; wherein the first scanning line section and the first reset control line section corresponding thereto are electrically connected to the scanning transfer structure corresponding thereto through via holes, and the second scanning line section and the second reset control line section corresponding thereto are electrically connected to the scanning transfer structure corresponding thereto through via holes; and wherein the scanning transfer structure corresponding to the first scanning line section is electrically connected to the row transfer line corresponding to the first scanning line section through a via hole; and the scanning transfer structure corresponding to the second scanning line section is electrically connected to the row transfer line corresponding to the second scanning line section through a via hole.

According to some embodiments of the present disclosure, the holing area includes a hole and an enclosing area surrounding the hole; the row line includes an enabling line for loading an enabling signal; a portion of the enabling line is separated by the holing area into a first enabling line section and a second enabling line section corresponding to each other; wherein the first enabling line section is electrically connected to the second enabling line section corresponding thereto through an enabling bypass line corresponding thereto that is arranged in the enclosing area.

According to some embodiments of the present disclosure, the display panel includes a first gate layer and a second gate layer arranged in stacked manner, the first gate layer is provided with the enabling line and a first electrode plate of a storage capacitor, and the second gate layer is provided with a second electrode plate of the storage capacitor; and the enabling bypass line is arranged in the first gate layer and/or the second gate layer.

According to some embodiments of the present disclosure, the holing area includes a hole and an enclosing area surrounding the hole, the row line includes an initialization line for loading an initialization voltage; a portion of the initialization line is separated by the holing area into a first initialization line section and a second initialization line section corresponding to each other; and the enclosing area is provided with a reference voltage bypass line surrounding the hole, and the first initialization line section and the second initialization line section are electrically connected to the reference voltage bypass line.

According to some embodiments of the present disclosure, the transfer line includes a row transfer line and a column transfer line; the row transfer line is configured to electrically connect the first row line section with the second row line section corresponding thereto; the column transfer line is configured to electrically connect the first column line section with the second column line section corresponding thereto; and a wiring space for the row transfer line is located within a wiring space for the column transfer line.

According to some embodiments of the present disclosure, the row transfer line is arranged on both sides of the holing area along the second direction, and the column transfer line is arranged on both sides of the holing area along the first direction; and the column transfer line is connected to the column line corresponding thereto through a column transfer via hole, the row transfer line is connected to the row line through a row transfer via hole, and a distance between the column transfer via hole and the holing area is greater than a distance between the row transfer via hole and the holing area.

According to some embodiments of the present disclosure, the transfer line, the row line, and the column line are arranged on different conductive layers.

According to some embodiments of the present disclosure, the display panel includes a base substrate, a driving circuit layer, and a pixel layer arranged in stacked manner in sequence; the driving circuit layer includes a first gate layer, a second gate layer, and a metal line layer arranged on a side of the base substrate in stacked manner in sequence, the row line is arranged in the first gate layer and the second gate layer, and the column line is arranged in the metal line layer; the driving circuit layer further includes a transfer line layer, the transfer line layer is located on a side of the first gate layer away from the second gate layer, or on a side of the metal line layer away from the second gate layer, or between adjacent layers among the first gate layer, the second gate layer, and the metal line layer; and the transfer line is arranged in the transfer line layer.

According to some embodiments of the present disclosure, the metal line layer includes a first source-drain metal layer; and the transfer line layer includes a second source-drain metal layer located on a side of the first source-drain metal layer away from the base substrate, and the transfer line is arranged in the second source-drain metal layer.

According to some embodiments of the present disclosure, the metal line layer includes a first source-drain metal layer and a second source-drain metal layer arranged on a side of the second gate layer away from the base substrate in stacked manner, and the column line is arranged in the second source-drain metal layer; and the transfer line layer includes a third source-drain metal layer located on a side of the second source-drain metal layer away from the base substrate, and the transfer line is arranged in the third source-drain metal layer.

According to some embodiments of the present disclosure, the display area includes a transfer area for arranging the transfer line and a non-transfer area surrounding the transfer area; and in the non-transfer area, the transfer line layer is provided with a resistance reduction structure for column line corresponding to at least a portion of the column line, and the resistance reduction structure for column line is electrically connected to the column line corresponding thereto through a via hole.

According to a second aspect of the present disclosure, an electronic device is provided, including a display panel as described above.

It should be understood that the general description above and the detailed description in the following are only illustrative and explanatory, and do not limit the present disclosure.

### BRIEF DESCRIPTION OF THE DRAWINGS

The drawings, which are incorporated in and constitute a part of this specification, illustrate embodiments consistent with the present disclosure and serve together with the specification to explain principles of the present disclosure. It is apparent that the drawings in the following description are only some embodiments of the present disclosure, and for those of ordinary skill in the art, other drawings can also be obtained from these drawings without creative efforts.

FIG. 1 is a schematic diagram of a portion of lines on a display panel according to some embodiments of the present disclosure.

FIG. 2 is a schematic diagram of a portion of lines in a transfer area of a display panel according to some embodiments of the present disclosure.

FIG. 3 is a schematic diagram of a portion of lines in a transfer area of a display panel according to some embodiments of the present disclosure.

FIG. 4 is a schematic diagram of a portion of lines in a transfer area of a display panel according to some embodiments of the present disclosure.

FIG. 5 is a schematic diagram of a portion of lines in a transfer area of a display panel according to some embodiments of the present disclosure.

FIG. 6 is a schematic diagram of distribution of row transfer lines in a local area of a transfer area according to some embodiments of the present disclosure.

FIG. 7 is a schematic diagram of distribution of column transfer lines in a local area of a transfer area according to some embodiments of the present disclosure.

FIG. 8 is a schematic diagram of a principle of a pixel driving circuit according to some embodiments of the present disclosure.

FIG. 9 is a schematic diagram of a structure of a semiconductor layer in a pixel driving area according to some embodiments of the present disclosure.

FIG. 10 is a schematic diagram of a structure of a first gate layer in a pixel driving area according to some embodiments of the present disclosure.

FIG. 11 is a schematic diagram of a structure of a second gate layer in a pixel driving area according to some embodiments of the present disclosure.

FIG. 12 is a schematic diagram of a structure of a first source-drain metal layer in a pixel driving area according to some embodiments of the present disclosure.

FIG. 13 is a schematic diagram of a structure of a second source-drain metal layer of a pixel driving circuit in a pixel driving area according to some embodiments of the present disclosure.

FIG. 14 is a schematic diagram of a structure of a first source-drain metal layer in a pixel driving area of a non-transfer area according to some embodiments of the present disclosure.

FIG. 15 is a schematic diagram of a structure of a second source-drain metal layer in a pixel driving area of a non-transfer area according to some embodiments of the present disclosure.

FIG. 16 is a schematic diagram of a structure of a film layer of a display panel according to some embodiments of the present disclosure.

FIG. 17 is a schematic diagram of a structure of a first source-drain metal layer, a second source-drain metal layer, and a portion of a gate layer in a transfer area according to some embodiments of the present disclosure.

FIG. 18 is a schematic diagram of a structure of a pixel electrode layer, a first source-drain metal layer, a second source-drain metal layer, and a portion of a gate layer in a transfer area according to some embodiments of the present disclosure.

### EXPLANATIONS OF REFERENCE NUMERALS

AA. Display area; A1. Transfer area; A2. Non-transfer area; BB. Peripheral area; B1. Binding area; CC. Holing area; C1. Enclosing area; C2. Hole; DH. First direction; DV. Second direction; DH1. First preset direction; DH2. Second preset direction; Haxis. Row central axis; Vaxis. Column central axis; PDCA. Pixel driving area; HPDC. Row of pixel driving circuits; VPDC. Column of pixel driving circuits; Gate. Scanning signal; Reset. Reset control signal; EM. Enabling signal; Vinit. Initialization voltage; VDD. Driving power voltage; VSS. Common power voltage; Data. Driving data; GL. Scanning line; GL1. First scanning line section; GL2. Second scanning line section; RL. Reset control line; RL1. First reset control line section; RL2. Second reset control line section; EML. Enabling line; EML1. First enabling line section; EML2. Second enabling line section; VinitL. Initialization line; DataL. Data line; DataL1. First data line section; DataL2. Second data line section; VDDL. Driving power line; VDDL1. First driving-power-line section; VDDL2. Second driving-power-line section; EMD. Enabling transfer structure; GD. Scanning transfer structure; VinitER. Reference voltage bypass line; HL. Row line; HL1. First row line section; HL2. Second row line section; VL. Column line; VL1. First column line section; VL2. Second column line section; TRL. Transfer line; HTRL. Row transfer line; H1TRL. First row transfer line; H2TRL. Second row transfer line; HTRL1. First row transfer line section; HTRL2. Second row transfer line section; HTRL3. Third row transfer line section; HTRL4. Fourth row transfer line section; HTRL5. Fifth row transfer line section; VTRL. Column transfer line; VTRL1. First column transfer line section; VTRL2. Second column transfer line section; VTRL3. Third column transfer line section.

### DETAILED DESCRIPTION

Example embodiments will now be described more fully with reference to the drawings. However, the example embodiments can be implemented in a variety of forms and should not be construed as being limited to the embodiments set forth herein. Rather, the provision of these embodiments makes the present disclosure comprehensive and complete and conveys ideas of the example embodiments in a comprehensive manner to those skilled in the art. The same reference numerals in the drawings indicate the same or similar structures, and thus their detailed description will be omitted. In addition, the drawings are only schematic illustrations of the present disclosure and are not necessarily drawn to scale.

Although relative terms such as “upper” and “lower” are used in this specification to describe a relative relationship of one component and another component, these terms are used in this specification only for convenience, for example, according to a direction of the example shown in the drawings. It will be appreciated that if the device illustrated is turned upside down, the component described as “upper” will become the “lower” component. When a certain structure is “on” another structure, it may mean that the certain structure is integrally formed on the other structure, or it may mean that the certain structure is “directly” arranged on the other structure, or that the certain structure is “indirectly” arranged on the other structure through yet another structure.

Terms “a”, “an”, “the”, “said” and “at least one” are used to indicate presence of one or more elements/components/etc. Terms “include” and “comprise” are used to indicate an open-ended inclusion, and mean presence of additional elements/components/etc., in addition to listed elements/components/etc. Terms “first”, “second”, “third”, etc., are used as markings only, instead of limiting the quantity of objects.

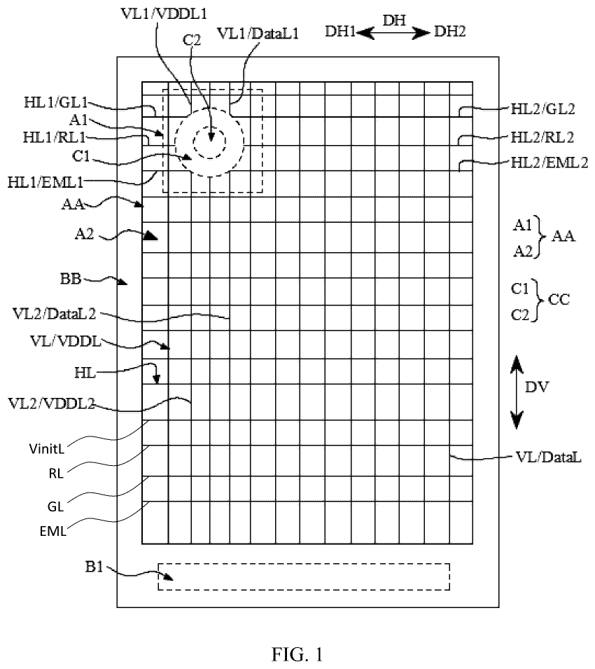

The present disclosure provides a display panel and an electronic device in which the display panel is applied. FIG. 1 is a top view of a structure of a display panel according to some embodiments of the present disclosure. As shown in FIG. 1, the display panel can include a holing area CC and a display area AA surrounding the holing area CC. In some embodiments, the holing area CC includes a hole C2 and an enclosing area C1 surrounding the hole C2 for packaging the hole C2. In the display area AA, sub pixels for displaying a screen and pixel driving circuits for driving the sub pixels are arranged. As shown in FIG. 1, the display panel is also provided with a peripheral area BB surrounding the display area AA. At one side of the peripheral area BB, a binding area B1 is arranged, which is used to bind and connect with an external circuit (such as a circuit board, a flexible circuit board, a COF (Chip On Film), etc.).

In the display panel provided in the present disclosure, the hole C2 allows the display panel to have a high transmittance. The hole can be a through hole that penetrates the display panel, or a sunken hole that thins or removes a portion of film layers of the display panel (a holing area that does not penetrate the display panel), which is not specially limited in the present disclosure. The electronic device of the present disclosure can be provided with a photosensitive component exactly facing the hole C2. The photosensitive component is arranged behind the display panel. The photosensitive component can receive light from the front of the display panel through the hole C2. The photosensitive component can be one or more light sensors, for example, a camera, an optical fingerprint recognition chip, a light intensity sensor, etc. In some embodiments, the photosensitive component can be a camera, for example, the photosensitive component can be a CCD (Charge Coupled Device) camera. In this way, the display device can achieve under screen shooting, which improves the screen ratio of the display device.

In some embodiments of the present disclosure, the hole C2 can be of a circular ship. The enclosing area C1 has an annular shape that surrounds the hole C2, with an outer edge thereof being of circular ship as a whole. It can be understood that the outer edge of the enclosing area C1 can be of a polygonal line shape locally or microstructurally, for example, the outer edge of the enclosing area C1 appears as a stepped shape locally. In the enclosing area C1, the display panel can be provided with a crack blocking dam, a water oxygen blocking wall, and other structures, as well as organic or inorganic packaging structures, to package and protect the display area AA. The hole C2 can also be of other shapes, such as a rectangular shape, an elliptical shape, etc. The number of holes C2 can be one or more.

In the display panel provided in the present disclosure, the display area AA is provided with a data line DataL for providing driving data ‘Data’ to the pixel driving circuit, and a scanning line GL for providing a scanning signal Gate to the pixel driving circuit. An extending direction of the data line DataL intersects with an extending direction of the scanning line GL. In some embodiments of the present disclosure, the extending direction along which the data line DataL extends can be defined as a second direction DV, and the extending direction along which the scanning line GL extends can be defined as a first direction DH. In some embodiments, the first direction DH intersects with the second direction DV. In some embodiments, the first direction DH and the second direction DV are perpendicular to each other. It can be understood that the first direction DH and the second direction DV can also be not perpendicular to each other.

In some embodiments of the present disclosure, as shown in FIG. 1, the holing area CC can be arranged at one end of the display area AA away from the binding area B1. In other words, along the second direction DV, the binding area B1 is located on one side of the display area AA, and the holing area CC is arranged away from the binding area B1.

In some embodiments of the present disclosure, as shown in FIG. 1, the holing area CC can be arranged near a top corner of the display area AA, for example, the holing area CC can be arranged at a top corner away from the binding area B1. Along the first direction DH, a direction along which the holing area CC close to one of the top corners of the display area AA can be defined as a first preset direction DH1, and a direction opposite to the first preset direction DH1 can be defined as a second preset direction DH2. The first preset direction DH1 and the second preset direction DH2 are two opposite directions along the first direction DH.

As shown in FIG. 1, the display panel can be provided with a row line HL extending along the first direction DH. For example, the row line HL includes one or more of the scanning line GL for loading the scanning signal Gate to the pixel driving circuit, a reset control line RL for loading a reset control signal Reset to the pixel driving circuit, an enabling line EML for loading an enabling signal EM to the pixel driving circuit, and an initialization line VinitL for loading an initialization voltage Vinit to the pixel driving circuit, etc. The driving circuit layer is also provided with a column line VL that extends along the second direction DV. For example, the column line VL includes one or more of the driving power line VDDL for loading the driving power voltage VDD to the pixel driving circuit, and the data line DataL for loading the driving data ‘Data’ to the pixel driving circuit, etc.

As shown in FIG. 1, some row lines HL are separated by the holing area CC into corresponding two sections, namely a first row line section HL1 and a second row line section HL2. In some embodiments, the first row line section HL1 is arranged on a side of the holing area CC to which the first preset direction DH1 directs, and the second row line section HL2 is arranged on a side of the holing area CC to which the second preset direction DH2 directs. some column lines VL are separated by the holing area CC into corresponding two sections, namely a first column line section VL1 and a second column line section VL2. In some embodiments, the first column line section VL1 is arranged on a side of the holing area CC away from the binding area B1, and the second column line section VL2 is arranged on a side of the holing area CC close to the binding area B1. In the related art, the separated column lines VL and row lines HL need to be electrically connected through bypass lines which are arranged in the enclosing area C1, to ensure the continuity of signals on both sides of the holing area CC, which results in a larger width of the enclosing area C1 due to the needing of too many bypass lines to be arranged in the enclosing area C1. As a result, it is necessary for the hole C1 to have a large border to be provided, and the holing area CC will have a large size, which is not conducive to improving the screen ratio of the display panel and the quality of the display image.

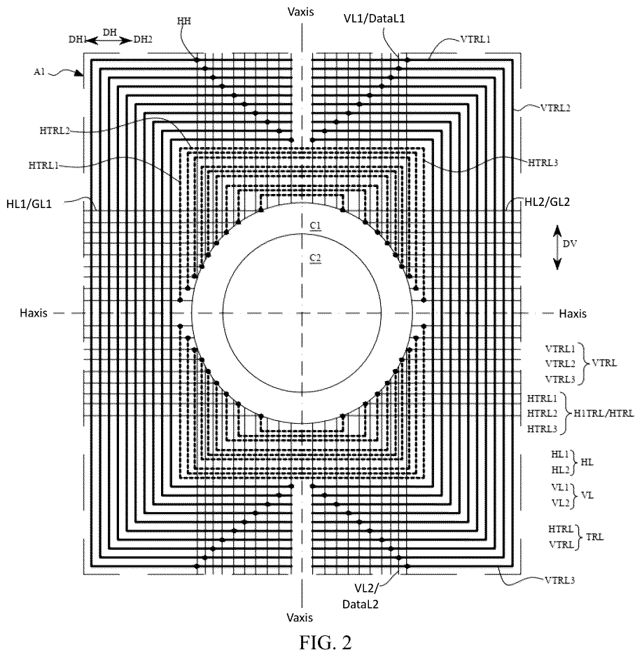

As shown in FIGS. 2 to 5, in the display panel of the present disclosure, a transfer line TRL is arranged in the display area AA. At least some of the first column line sections VL1 are electrically connected to the corresponding second column line sections VL2 through the corresponding transfer lines TRL located in the holing area CC, and/or, at least some of the first row line sections HL1 are electrically connected to the corresponding second row line sections HL2 through the corresponding transfer lines TRL located in the holing area CC. In this way, the number of the bypass lines arranged in the enclosing area C1 can be reduced, thereby reducing the width of the enclosing area C1, and achieving narrow border of the holing area CC, and thus reducing the size of the holing area CC, and improving the screen ratio of the electronic device and display quality. In some embodiments, the width of the enclosing area C1 can be reduced to 0.5-0.6 millimeters.

In some embodiments of the present disclosure, some of the transfer lines TRL can be used to ensure signal continuity in at least some of the row lines HL separated by the holing area CC, and the remaining transfer lines TRL can be used to ensure signal continuity in at least some of the column lines VL separated by the holing area CC. In other words, some transfer lines TRL are used to electrically connect first row line sections HL1 to corresponding second row line sections HL2, and the remaining transfer lines TRL are used to electrically connect first column line sections VL1 to corresponding second column line sections VL2. In some embodiments of the present disclosure, all transfer lines TRL can be used to ensure signal continuity in at least some row lines HL separated by the holing area CC, or all transfer lines TRL can be used to ensure signal continuity in at least some column lines VL separated by the holing area CC.

Further introductions and explanations of the display panel of the present disclosure will be provided in the following from the perspective of film layers.

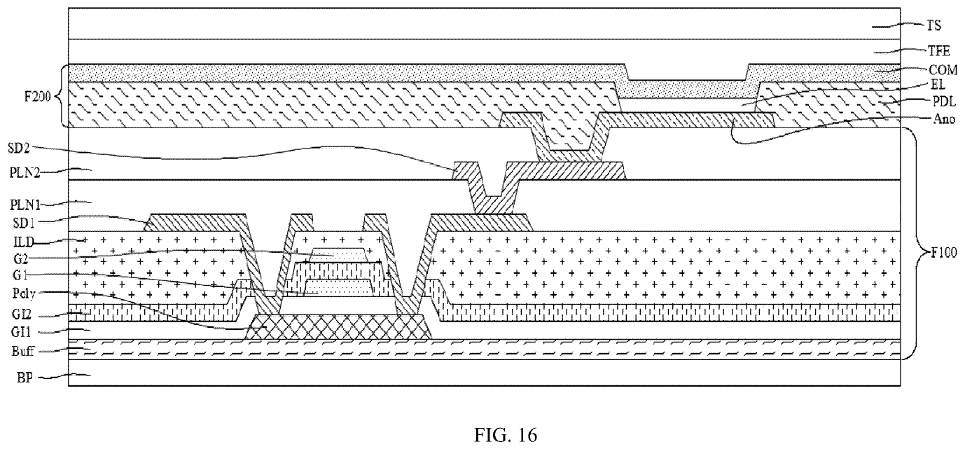

As shown in FIG. 16, the display panel of the present disclosure includes a base substrate BP, a driving circuit layer F100, and a pixel layer F200 arranged in stacked manner in sequence. In some embodiments, the pixel layer is provided with light-emitting elements as sub pixels, and the driving circuit layer is provided with pixel driving circuits for driving sub pixels.

The base substrate BP can be a base substrate made of an inorganic material or an organic material. For example, in some embodiments of the present disclosure, the material of the base substrate BP can be glass materials such as soda-lime glass, quartz glass, sapphire glass, etc., or metal materials such as stainless steel, aluminum, nickel, etc. In some embodiments of the present disclosure, the material of the base substrate BP can be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET) polyethylene naphthalate (PEN) or combinations thereof. In some embodiments of the present disclosure, the base substrate BP can also be a flexible base substrate, for example, the material of the base substrate BP can include polyimide (PI).

The driving circuit layer F100 is provided with pixel driving circuits for driving sub pixels. In the driving circuit layer F100, any of the pixel driving circuits can include a transistor and a storage capacitor. In some embodiments, the transistor can be a thin film transistor, which can be selected from a top gate thin film transistor, a bottom gate thin film transistor, or a double gate thin film transistor. A material of an active layer of the thin film transistor can be amorphous silicon semiconductor materials, low-temperature polycrystalline silicon semiconductor materials, metal oxide semiconductor materials, organic semiconductor materials, or other types of semiconductor materials. The thin film transistor can be either an N-type thin film transistor or a P-type thin film transistor.

It can be understood that among the transistors in the pixel driving circuits, the types between any two transistors can be the same or different. For example, in some embodiments, in one pixel driving circuit, some transistors can be N-type transistors and some transistors can be P-type transistors. In some embodiments of the present disclosure, in one pixel driving circuit, the materials of the active layers of some transistors can be low-temperature polycrystalline silicon semiconductor materials, and the materials of the active layers of some transistors can be metal oxide semiconductor materials. In some embodiments of the present disclosure, the thin film transistors are low-temperature polycrystalline silicon transistors. In some embodiments of the present disclosure, some thin film transistors are low-temperature polycrystalline silicon transistors, and some thin film transistors are metal oxide transistors.

The transistor can have a first terminal, a second terminal, and a control terminal. One of the first terminal and the second terminal can be a source of the transistor and the other one can be a drain of the transistor, and the control terminal can be a gate of the transistor. It can be understood that the source and the drain of the transistor are two relative and interchangeable concepts. When an operating state of the transistor changes, for example, when a current direction changes, the source and the drain of the transistor can be interchanged.

In the display panel provided in the present disclosure, the driving circuit layer can include multiple conductive layers for arranging lines such as the row line HL, the column line VL, the transfer line TRL, etc. In some embodiments, the row line, the column line, and the transfer line can be respectively arranged on different conductive layers.

In some embodiments of the present disclosure, the driving circuit layer can include a gate layer (such as stacked first gate layer and second gate layer) and a metal line layer arranged on one side of the base substrate in stacked manner in sequence. The gate layer is used for arranging the row line, and the metal line layer is used for arranging the column line. The driving circuit layer further includes a transfer line layer. The transfer line layer is arranged on a side of the first gate layer away from the second gate layer, or arranged on a side of the metal line layer away from the second gate layer, or between adjacent layers among the first gate layer, the second gate layer, and the metal line layer. The transfer line is arranged in a transfer line layer. In this way, it can ensure that the column line VL, the row line HL, and the transfer line TRL can avoid each other.

In some embodiments, the metal line layer includes a first source-drain metal layer. The transfer line layer includes a second source-drain metal layer located on a side of the first source-drain metal layer away from the base substrate. The transfer line is arranged in the second source-drain metal layer. In this way, the conductive layers of the driving circuit layer include the first gate layer, the second gate layer, the first source-drain metal layer, and the second source-drain metal layer sequentially arranged on one side of the base substrate. The column line is arranged in the first source-drain metal layer, and the transfer line is arranged in the second source-drain metal layer.

In some embodiments, the metal line layer includes a first source-drain metal layer and a second source-drain metal layer arranged on a side of the second gate layer away from the base substrate in stacked manner. The column line is arranged in the second source-drain metal layer. The transfer line layer includes a third source-drain metal layer located on a side of the second source-drain metal layer away from the base substrate. The transfer line is arranged in the third source-drain metal layer. In this way, the conductive layers of the driving circuit layer include the first gate layer, the second gate layer, the first source-drain metal layer, the second source-drain metal layer, and the third source-drain metal layer sequentially arranged on one side of the base substrate. The column line is arranged in the second source-drain metal layer, and the transfer line is arranged in the third source-drain metal layer.

In some embodiments, as shown in FIG. 1, the display area AA includes a transfer area A1 for arranging the transfer line TRL, as well as a non-transfer area A2 surrounding the transfer area A1. As shown in FIG. 15, in the non-transfer area A2, the transfer line layer is provided with a resistance reduction structure VLD for column line corresponding to at least some of the column lines VL (for example, a resistance reduction structure VDDLD for driving power line, and a resistance reduction structure DataLD for data line in FIG. 15). The resistance reduction structure VLD for column line is electrically connected to the corresponding column line VL through a via hole. In some embodiments, the resistance reduction structure VLD for column line and the column line VL corresponding thereto extend along the same direction, and they are arranged in overlapped manner and electrically connected to each other through multiple via holes.

In some embodiments of the present disclosure, the transfer line layer can also be provided with a resistance reduction structure for row line HL corresponding to at least some of the row lines HL, and the resistance reduction structure for row line is electrically connected to the corresponding row line HL through a via hole. The resistance reduction structure for row line can adjust the load on the row line, so as to improve the uniformity of the load on the row line, and reduce the inconsistency of load on different row lines due to the lack of sub pixels in the holing area.

The driving circuit layer can also include other film layers, such as a semiconductor layer, an insulation layer, a passivation layer, a planarization layer, etc. The semiconductor layer can be a polycrystalline silicon semiconductor layer (such as a low-temperature polycrystalline silicon semiconductor layer), or a metal oxide semiconductor layer (such as an IGZO layer), or the semiconductor layer can include stacked polycrystalline silicon semiconductor layer, metal oxide semiconductor layer, etc. The relationship of stacked film layers can be determined based on a film structure of the thin film transistor. In the driving circuit layer, the semiconductor layer can be used to form the active layer of the transistor. The gate layer can be used to form the lines in the gate layer such as the scanning line, the reset control line, etc. The gate layer can also be used to form the gate of the transistor, and to form part or all of the electrode plates of a storage capacitor. The source-drain metal layer can be used to form the lines in the source-drain metal layer such as the data line, the power line, etc. The source-drain metal layer can also be used to form part or all of the electrode plates of a storage capacitor.

Exemplary explanations and illustrations of the film layer structure of the driving circuit layer will be provided in the following, taking a driving circuit layer including two gate layers and two source-drain metal layers as an example.

As shown in FIG. 16, the driving circuit layer F100 provided by embodiments can include a semiconductor layer Poly, a first gate insulation layer GI1, a first gate layer G1, a second gate insulation layer GI2, a second gate layer G2, an interlayer dielectric layer ILD, a first source-drain metal layer SD1, a first planarization layer PLN1, a second source-drain metal layer SD2, and a second planarization layer PLN2, etc., arranged between the base substrate BP and the pixel layer F200 in stacked manner. These film layers can form various transistors, storage capacitors, column lines, row lines, and transfer lines. In some embodiments, the channel region of the transistor is formed in the semiconductor layer Poly, the first electrode plate of the storage capacitor is formed in the first gate layer, and the second electrode plate of the storage capacitor is formed in the second gate layer. In some examples, the driving circuit layer F100 can also include a passivation layer, which can be arranged on a surface of the source-drain metal layer away from the base substrate BP, so as to protect the source-drain metal layer. In some embodiments, the passivation layer can include a first passivation layer arranged on a surface of the first source-drain metal layer and a second passivation layer arranged on a surface of the second source-drain metal layer.

In some embodiments, the driving circuit layer F100 can further include a buffer material layer Buff arranged between the base substrate BP and the semiconductor layer Poly, and the semiconductor layer Poly, the gate layer, etc. are all located on a side of the buffer material layer Buff away from the base substrate BP. The material of the buffer material layer can be inorganic insulation materials such as silicon oxide and silicon nitride. The buffer material layer can be one layer of inorganic material or multiple layers of inorganic material.

The pixel layer F200 can be provided with light-emitting elements arranged in an array, serving as sub pixels, and each of the light-emitting elements emits light under the control of the pixel driving circuit. In the present disclosure, the light-emitting elements can be organic light-emitting diodes (OLEDs), micro light-emitting diodes (Micro LEDs), quantum dot organic light-emitting diodes (QD-OLED), quantum dot light-emitting diodes (QLEDs), or other types of light-emitting elements. According to some embodiments of the present disclosure, if the light-emitting element is an organic light-emitting diode (OLED), the display panel is an OLED display panel. The structure of the pixel layer will be introduced, taking the light-emitting element is an organic light-emitting diode as an example.

In some embodiments, as shown in FIG. 16, the pixel layer F200 can be arranged on a side of the driving circuit layer F100 away from the base substrate BP, which can include a pixel electrode layers Ano, a pixel definition layer PDL, a support cylinder layer (not shown in FIG. 16), an organic electro-luminescence layer EL, and a common electrode layer COM arranged in stacked manner in sequence. In some embodiments, the pixel electrode layer Ano includes multiple pixel electrodes in the display area of the display panel. The pixel definition layer PDL includes multiple through pixel openings in the display area corresponding to the multiple pixel electrodes one by one, and any one pixel exposes at least a portion of the pixel electrode corresponding thereto. The support cylinder layer includes multiple support cylinders in the display area, and the support cylinders are located on a surface of the pixel definition layer PDL away from the base substrate BP, so as to support a fine metal mask (FMM) during the evaporation process. The organic electro-luminescence layer EL covers at least the pixel electrode exposed by the pixel definition layer PDL. In some embodiments, the organic electro-luminescence layer EL can include an organic electroluminescent material layer, as well as one or more of hole injection layer, hole transport layer, electron blocking layer, hole blocking layer, electron transport layer, and electron injection layer. The various film layers of the organic electro-luminescence layer EL can be prepared through the evaporation process, and the patterns of each film layer can be defined using the fine metal mask or an open mask during the evaporation process. The common electrode layer COM can cover the organic electro-luminescence layer EL in the display area. In this way, the pixel electrode, the common electrode layer COM, and the organic electro-luminescence layer EL located between the pixel electrode and the common electrode layer COM form an organic light-emitting diode, and any one of the organic light-emitting diodes can serve as one sub pixel of the display panel.

In some embodiments, the pixel layer F200 can further include a light extraction layer located on a side of the common electrode layer COM away from the base substrate BP, so as to enhance the output efficiency of the organic light-emitting diode.

In some embodiments, the display panel can further include a thin film encapsulation layer TFE. The thin film encapsulation layer TFE is located on a surface of the pixel layer F200 away from the base substrate BP, and can include inorganic encapsulation layers and organic encapsulation layers arranged in stacked manner alternatively. In some embodiments, the inorganic encapsulation layer can effectively block external moisture and oxygen, avoiding the invasion of water and oxygen into the organic electro-luminescence layer EL and causing material degradation. In some embodiments, the edges of the inorganic encapsulation layer can be located in the peripheral area. The organic encapsulation layer is located between two adjacent inorganic encapsulation layers to achieve planarization and reduce stress between the inorganic encapsulation layers. In some embodiments, the edges of the organic encapsulation layer can be located between the edges of the display area and the edges of the inorganic encapsulation layer. For example, the thin film encapsulation layer TFE includes a first inorganic encapsulation layer, an organic encapsulation layer, and a second inorganic encapsulation layer arranged on a side of the pixel layer F200 away from the base substrate BP in stacked manner in sequence. It can be understood that the thin film encapsulation layer TFE also encapsulates the display area AA in the enclosing area C1, so as to protect the sub pixels in the display area and prevent water and oxygen from invading the display area AA from the hole C2.

In some embodiments, the display panel can further include a touch functional layer TS, which is located on a side of the thin film encapsulation layer TFE away from the base substrate BP, and the touch functional layer TS is used for touch operation on the display panel.

In some embodiments, the display panel can further include a reflection reduction layer, which can be arranged on a side of the thin film encapsulation layer away from the pixel layer, so as to reduce the reflection of the display panel on ambient light, thereby reducing the impact of the ambient light on the display effect. In some embodiments of the present disclosure, the reflection reduction layer can include a color film layer and a black matrix layer arranged in stacked manner, which can reduce the interference from the environmental light while avoiding a decrease in the transmittance of the display panel. In some embodiments of the present disclosure, the reflection reduction layer can be a polarizer, for example, a patterned coated circular polarizer. In some embodiments, the reflection reduction layer can be arranged on a side of the touch functional layer away from the base substrate BP.

In some embodiments of the present disclosure, as shown in FIGS. 2 to 5, the transfer line TRL can include a row transfer line HTRL for ensuring the signal continuity in the row line HL, and a column transfer line VTRL for ensuring the signal continuity in the column line VL. In some embodiments, the first column line section VL1 is electrically connected to the corresponding second column line section VL2 through the column transfer line VTRL corresponding thereto, and the first row line section HL1 is electrically connected to the corresponding second row line section HL2 through the row transfer line HTRL corresponding thereto.

In some embodiments of the present disclosure, compared to the row transfer line HTRL, the column transfer line VTRL is arranged far away from the holing area CC. In other words, a wiring space for the row transfer line HTRL is located within a wiring space for the column transfer line VTRL. In some embodiments of the present disclosure, compared to the column transfer line VTRL, the row transfer line HTRL can also be further away from the holing area CC.

In some embodiments of the present disclosure, the row transfer line HTRL is electrically connected to the corresponding row line HL through a row transfer via hole, and the column transfer line VTRL is electrically connected to the corresponding column line VL through a column transfer via hole. In some embodiments, the row transfer via hole is formed in the insulation layer adjacent to the transfer line layer and overlaps with the row transfer line HTRL. The column transfer via hole is formed in the insulation layer adjacent to the transfer line layer and overlaps with the column transfer line VTRL. A distance between the column transfer via hole and the holing area is greater than a distance between the row transfer via hole and the holing area.

In some embodiments of the present disclosure, the row transfer line is distributed on both sides of the holing area along the second direction, and the column transfer line is distributed on both sides of the holing area along the first direction.

In some embodiments, according to the wiring way of the row transfer line HTRL, the row transfer line HTRL can be divided into two different types, namely a first row transfer line H1TRL and a second row transfer line H2TRL. In the display panel of the present disclosure, the row transfer line HTRL can include only the first row transfer line H1TRL or only the second row transfer line H2TRL, or the row transfer line HTRL can also include both the first row transfer line H1TRL and the second row transfer line H2TRL.

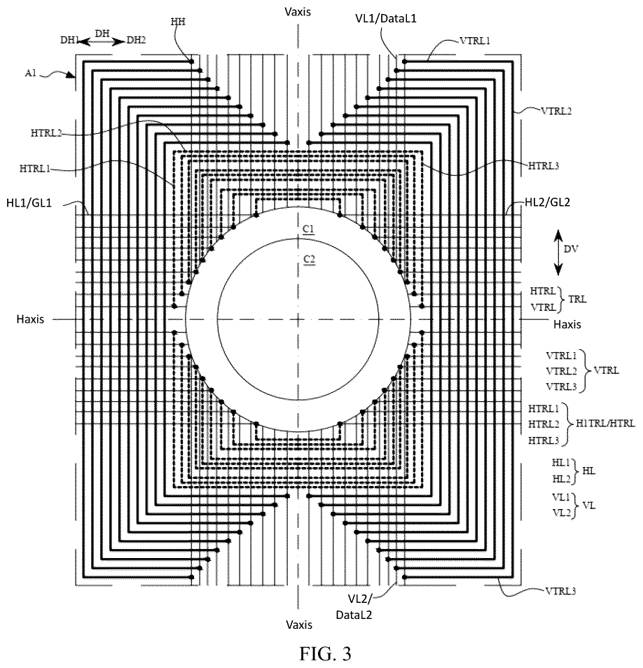

As shown in FIG. 2 and FIG. 3, the first row transfer line H1TRL can include a first row transfer line section HTRL1, a second row transfer line section HTRL2, and a third row transfer line section HTRL3 connected in sequence. In some embodiments, the first row transfer line section HTRL1 and the third row transfer line section HTRL3 extend along the second direction DV, and the second row transfer line section HTRL2 extends along the first direction DH. The first row transfer line section HTRL1 is electrically connected to the first row line section HL corresponding thereto, and the third row transfer line section HTRL3 is electrically connected to the second row line section HL2 corresponding thereto. In other words, the first row transfer line H1TRL is electrically connected to the corresponding first row line section HL1 through the first row transfer line section HTRL1. For example, the first row transfer line H1TRL is electrically connected to the corresponding first row line section HL1 through an end of the first row transfer line section HTRL1 away from the second row transfer line section HTRL2. The first row transfer line H1TRL is electrically connected to the corresponding second row line section HL2 through the third row transfer line section HTRL3. For example, the first row transfer line H1TRL is electrically connected to the corresponding second row line section HL2 through an end of the third row transfer line section HTRL3 away from the second row transfer line section HTRL2. The second row transfer line section HTRL2 can be arranged on a side of the holing area CC close to or away from the binding area B1.

In some embodiments of the present disclosure, as shown in FIGS. 2 and 3, the row transfer lines HTRL are all first row transfer lines H1TRL.

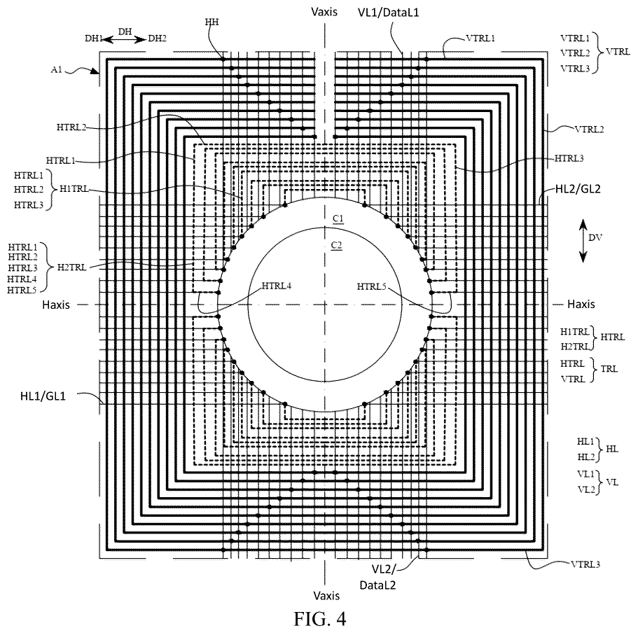

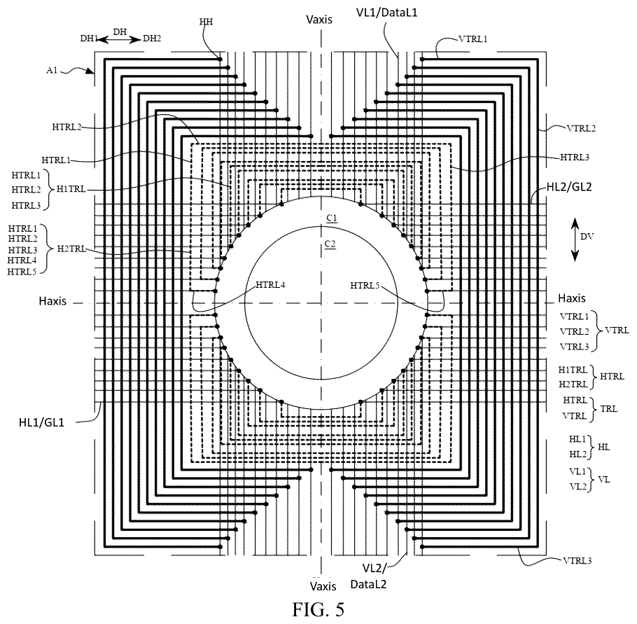

As shown in FIGS. 4 and 5, the second row transfer line H2TRL includes a fourth row transfer line section HTRL4, a first row transfer line section HTRL1, a second row transfer line section HTRL2, a third row transfer line section HTRL3, and a fifth row transfer line section HTRL5 connected in sequence. The first row transfer line section HTRL1 and the third row transfer line section HTRL3 extend along the second direction DV, and the fourth row transfer line section HTRL4, the second row transfer line section HTRL2, and the fifth row transfer line section HTRL5 extend along the first direction DH. The second row transfer line H2TRL is electrically connected to the corresponding first row line section HL1 through the fourth row transfer line section HTRL4. For example, the second row transfer line H2TRL is electrically connected to the corresponding first row line section HL1 through an end of the fourth row transfer line section HTRL4 away from the first row transfer line section HTRL1. The second row transfer line H2TRL is electrically connected to the corresponding second row line section HL2 through the fifth row transfer line section HTRL5. For example, the second row transfer line H2TRL is electrically connected to the corresponding second row line section HL2 through an end of the fifth row transfer line section HTRL5 away from the third row transfer line section HTRL3.

In some embodiments of the present disclosure, as shown in FIGS. 4 and 5, some of the row transfer lines HTRL are the first row transfer lines H1TRL, and remaining row transfer lines HTRL are the second row transfer lines H2TRL. In some embodiments, along the second direction DV, the first row line section HL1 corresponding to the second row transfer line H2TRL is arranged close to the middle of the holing area CC, and first row line section HL1 corresponding to the first row transfer line H1TRL is arranged close to an end part of the holing area CC.

In some embodiments of the present disclosure, all row transfer lines HTRL can be the second row transfer lines H2TRL.

In some embodiments of the present disclosure, as shown in FIGS. 2 to 5, the holing area CC has a row central axis Haxis that extends along the first direction DH, and the row central axis Haxis passes through a geometric center of the holing area CC. The row transfer line HTRL corresponding to the first row line section HL1 located on one side of the row central axis Haxis is on the same side of the row central axis Haxis. In other words, the second row transfer line section HTRL2 that is connected with the row line HL located on a side of the row central axis Haxis close to the binding area B1 is located on a side of the holing area CC close to the binding area B1. The second row transfer line section HTRL2 that is connected with the row line HL located on a side of the row central axis Haxis away from the binding area B1 is located on a side of the holing area CC away from the binding area B1.

In some embodiments, for the second row transfer line sections HTRL2 electrically connected with two adjacent first row line sections HL1, the second row transfer line section HTRL2 electrically connected with the first row line section HL1 that is located away from the row central axis Haxis is arranged close to the holing area CC. In other words, on the same side of the row central axis Haxis, the farther a distance between the first row line section HL1 and the row central axis Haxis, the closer a distance from the second row transfer line section HTRL2 electrically connected with the first row line section HL1 to the holing area CC.

In some embodiments, as shown in FIGS. 2 and 3, the first row transfer line H1TRL presents as a “ [symbol] (a Chinese radical)” shape to form an acceptance space. For the first row transfer lines H1TRL connected with two adjacent first row line sections HL1, the first row transfer line H1TRL connected with the first row line section HL1 that is away from the row central axis Haxis is located in the acceptance space of the first row transfer line H1TRL connected with the first row line section HL1 that is close to the row central axis Haxis.

In some embodiments of the present disclosure, the row line HL includes the scanning line GL. Some of the scanning lines GL are separated by the holing area CC into a first scanning line section GL1 and a second scanning line section GL2 located on both sides of the holing area CC, corresponding to each other. The first scanning line section GL1 is located on a side of the holing area CC to which the first preset direction DH1 directs, and the second scanning line section GL2 is located on a side of the holing area CC to which the second preset direction DH2 directs. The first scanning line section GL1 and the second scanning line section GL2 corresponding thereto are electrically connected to each other through the corresponding row transfer line HTRL.

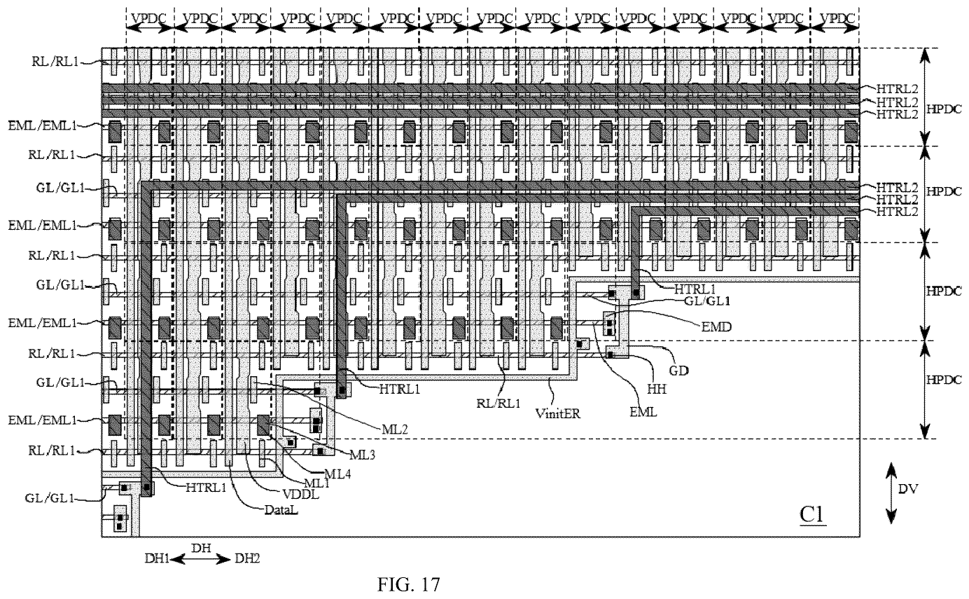

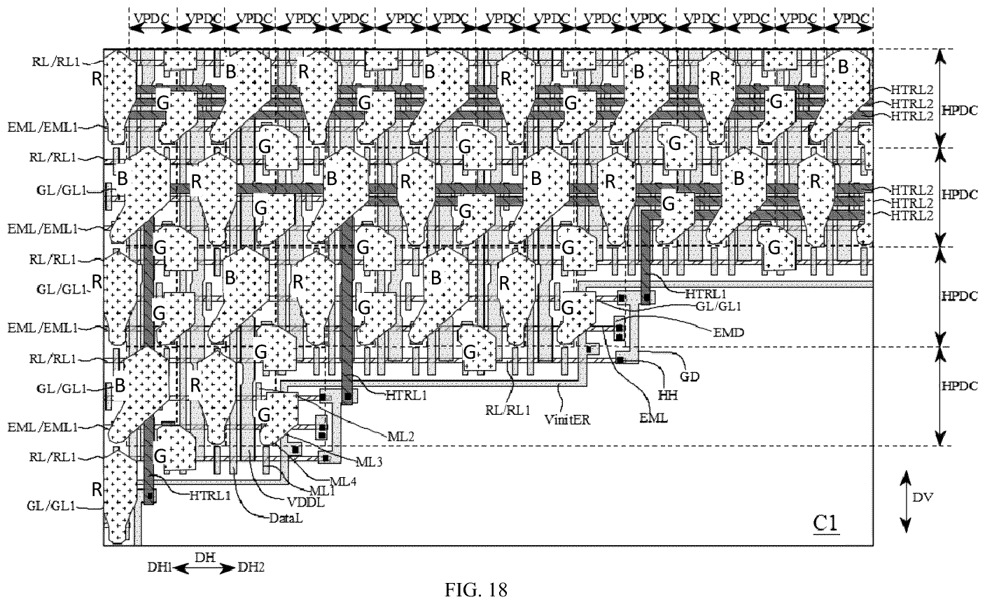

In some embodiments, the driving circuit layer includes a first gate layer G1, a second gate layer G1, a first source-drain metal layer SD1, and a second source-drain metal layer SD2 arranged in stacked manner in sequence. The scanning line GL is arranged in the first gate layer G1, and the row transfer line HTRL is arranged in the second source-drain metal layer SD2. As shown in FIG. 17, in the enclosing area C1, the first source-drain metal layer SD1 is provided with scanning transfer structures GD corresponding to the first scanning line section GL1 and the second scanning line section GL2. The scanning transfer structure GD corresponding to the first scanning line section GL1 is electrically connected to the first scanning line section GL1 through a via hole. For example, the scanning transfer structure GD corresponding to the first scanning line section GL1 is electrically connected to a tail end (close to an end of the holing area CC) of the first scanning line section GL1 through a via hole. The scanning transfer structure GD corresponding to the second scanning line section GL2 is electrically connected to the second scanning line section GL2 through a via hole. For example, the scanning transfer structure GD corresponding to the second scanning line section GL2 is electrically connected to a tail end (close to an end of the holing area CC) of the second scanning line section GL2 through a via hole. The row transfer line HTRL corresponding to the scanning line GL is electrically connected, at one end thereof, to the scanning transfer structure GD corresponding to the first scanning line section GL1 through a via hole, and is electrically connected, at the other end thereof, to the scanning transfer structure GD corresponding to the second scanning line section GL2 through a via hole.

In some embodiments of the present disclosure, the first scanning line section GL1 and the second scanning line section GL2 can also be electrically connected through a bypass line arranged in the enclosing area C1.

In some embodiments of the present disclosure, for the second row transfer line H2TRL, the fourth row transfer line section HTRL4 and the corresponding first scanning line section GL1 are arranged in overlapped manner, and the fifth row transfer line section HTRL5 and the corresponding second scanning line section GL2 are arranged in overlapped manner. In other words, the fourth row transfer line section HTRL4 and the corresponding first scanning line section GL1 extend substantially in parallel and proceed side by side along the first direction DH, and an overlapping part of orthographic projections of the fourth row transfer line section HTRL4 and the first scanning line section GL1 on the base substrate BP extends along the first direction DH. The fifth row transfer line section HTRL5 and the corresponding second scanning line section GL2 extend substantially in parallel and proceed side by side along the first direction DH, and an overlapping part of orthographic projections of the fifth row transfer line section HTRL5 and the second scanning line section GL2 on the base substrate BP extends along the first direction DH. In this way, the interference received by the second row transfer line H2TRL can be reduced.

In some embodiments of the present disclosure, the row line HL includes an enabling line EML. Some of the enabling lines EML are separated by the holing area CC into a first enabling line section EML1 and a second enabling line section EML2 located on both sides of the holing area CC, corresponding to each other. The first enabling line section EML1 is located on a side of the holing area CC to which the first preset direction DH1 directs, and the second enabling line section EML2 is located on a side of the holing area CC to which the second preset direction DH2 directs. The first enabling line section EML1 and the second enabling line section EML2 corresponding thereto are electrically connected to each other through the corresponding row transfer line HTRL.

In some embodiments of the present disclosure, the first enabling line section EML1 and the second enabling line section EML2 corresponding thereto can also be electrically connected through a corresponding enabling bypass line arranged in the enclosing area C1. In some embodiments, the display panel includes a first gate layer and a second gate layer arranged in stacked manner. The first gate layer is provided with the enabling line EML and the first electrode plate of the storage capacitor, and the second gate layer is provided with the second electrode plate of the storage capacitor, with the enabling bypass line being arranged in the first gate layer and/or the second gate layer.

In some embodiments, the enabling bypass lines can be alternately arranged in the first gate layer and the second gate layer, so as to reduce the spacing between adjacent enabling bypass lines, and thus further reducing the width of the enclosing area C1, and achieving a narrower border of the holing area on the display screen.

In some embodiments, as shown in FIGS. 17 and 18, the first source-drain metal layer SD1 can be provided in the enclosing area C1 with enabling transfer structures EMD corresponding to the first enabling line section EML1 and the second enabling line section EML2. A tail end (close to an end of the holing area CC) of the first enabling line section EML1 is electrically connected to the enabling transfer structure EMD corresponding thereto through a via hole, and a tail end (close to an end of the holing area CC) of the second enabling line section EML2 is electrically connected to the enabling transfer structure EMD corresponding thereto through a via hole. The enabling bypass line (not shown in FIGS. 17 and 18) corresponding to the first enabling line section EML1 and the second enabling line section EML2 is electrically connected, at both ends, to the enabling transfer structure EMD corresponding to the first enabling line section EML1 and the enabling transfer structure EMD corresponding to the second enabling line section EML2 through via holes.

In some embodiments of the present disclosure, the row line HL includes an initialization line VinitL. In some embodiments, some of the initialization lines VinitL are separated by the holing area CC into a first initialization line section and a second initialization line section located on both sides of the holing area CC, corresponding to each other. The first initialization line section and the second initialization line section corresponding thereto are electrically connected to each other through the row transfer line HTRL.

In some embodiments, the initialization line VinitL that is separated by the holing area CC can also maintain its signal continuity in other ways. In some embodiments, an initialization voltage bus can be arranged on both sides of the display area AA which are along the first direction, and both ends of the initialization line VinitL are electrically connected to the initialization voltage buses at both sides. In this way, both ends of the initialization line VinitL that is not separated by the holing area CC can be loaded with an initialization voltage Vinit through the initialization voltage buses. The first initialization line section and the second initialization line section can obtain the initialization voltage Vinit respectively through an adjacent initialization voltage bus. In some embodiments, as shown in FIGS. 17 and 18, the enclosing area C1 is provided with a reference voltage bypass line VinitER surrounding the hole C2. Each of the first initialization line sections (not shown in FIGS. 17 and 18) and each of the second initialization line sections (not shown in FIGS. 17 and 18) are electrically connected to the reference voltage bypass line VinitER. In this way, the voltage drop on the first initialization line section and the second initialization line section can be reduced, which is thus conducive to the uniformity of the display panel.

In some embodiments of the present disclosure, the row line HL includes a reset control line RL. In some embodiments, some of the reset control lines RL are separated by the holing area CC into a first reset control line section RL1 and a second reset control line section RL2 located on both sides of the holing area CC, corresponding to each other. The first reset control line section RL1 and the second reset control line section RL2 corresponding thereto are electrically connected to each other through a row transfer line HTRL. In some embodiments of the present disclosure, the first reset control line section RL1 and the second reset control line section RL2 can also be electrically connected through a bypass line arranged in the enclosing area C1.

In some embodiments, for the reset control lines RL adjacent to the scanning line GL, a signal on one of the reset control lines RL and a signal on the scanning line GL are the same (for example, at a high level or at a low level at the same time), the scanning line GL and the reset control line RL loaded with the same signal can be used as corresponding scanning line GL and reset control line RL. In some embodiments, the first scanning line section GL1 and the first reset control line section RL1 corresponding thereto are arranged side by side, and are electrically connected to the same first row transfer line section HTRL1. The second scanning line section GL2 and the second reset control line section RL2 corresponding thereto are arranged side by side, and are electrically connected to the same third row transfer line section HTRL3. In this way, there is no need of arranging additionally a dedicated row transfer line HTRL for the signal continuity of the reset control line RL, which can reduce the number of row transfer lines HTRL, reduce the wiring space for the row transfer lines HTRL, and improve the uniformity of the display panel.

In some embodiments of the present disclosure, as shown in FIGS. 17 and 18, the enclosing area C1 is provided with scanning transfer structures GD corresponding to the first scanning line section GL1 and the second scanning line section GL2 one by one. The first scanning line section GL1 and the corresponding first reset control line section RL1 are electrically connected with the scanning transfer structure GD corresponding thereto. The second scanning line section GL2 and the corresponding second reset control line section RL2 are electrically connected with the scanning transfer structure GD corresponding thereto.

In some embodiments, the scanning line GL and the corresponding reset control line RL are arranged on the same conductive layer, for example, both are located on the first gate layer. The scanning line GL, the scanning transfer structure GD, and the row transfer line HTRL are located in different conductive layers. The first scanning line section GL1 and the first reset control line section RL1 corresponding thereto are electrically connected to the corresponding scanning transfer structure GD through a via hole. The second scanning line section GL2 and the second reset control line section RL2 corresponding thereto are electrically connected to the corresponding scanning transfer structure GD through a via hole. The scanning transfer structure GD corresponding to the first scanning line section GL1 is electrically connected to the row transfer line HTRL corresponding to the first scanning line section GL1 through a via hole. The scanning transfer structure GD corresponding to the second scanning line section GL2 is electrically connected to the row transfer line HTRL corresponding to the second scanning line section GL2 through a via hole.

In some embodiments, as shown in FIG. 1, the row line HL includes the initialization line VinitL, the scanning line GL, the reset control line RL, and the enabling line EML. In some embodiments, for the initialization lines VinitL separated by the holing area CC, the first initialization line section and the second initialization line section are respectively electrically connected to the initialization voltage buses adjacent to them. The first initialization line section and the second initialization line section are not electrically connected to each other through the row transfer line HTRL located in the display area AA.

As shown in FIG. 17, the enclosing area C1 is provided with a reference voltage bypass line VinitER surrounding the hole C2. Ends of the first initialization line section and the second initialization line section that are close to the holing area CC are electrically connected to the reference voltage bypass line VinitER. For the enabling line EML separated by the holing area CC, the first enabling line section EML1 and the second enabling line section EML2 corresponding thereto are electrically connected through the enabling bypass line arranged in the enclosing area C1. For the scanning line GL and the reset control line RL separated by the holing area CC, the first scanning line section GL1 and the first reset control line section RL1 which are loaded with the same signal are electrically connected to the same first row transfer line section HTRL1, and the second scanning line section GL2 and the second reset control line section RL2 which are loaded with the same signal are electrically connected to the same third row transfer line section HTRL3, so that the first scanning line section GL1 loaded with the same signal and the second scanning line section GL2 are electrically connected to the third section HTRL3 of the same line transfer, so that the first scanning line section GL1, the second scanning line section GL2, the first reset control line section RL1, and the second reset control line section RL2, which are loaded with the same signal, are electrically connected through the same row transfer line HTRL.

In some embodiments, as shown in FIG. 2, the farther a distance between the first scanning line section GL1 and the row central axis Haxis of the holing area CC, the closer a distance from the second row transfer line section HTRL2 of the row transfer line HTRL connected to the first scanning line section GL1 to the holing area CC. In this way, the wiring space for the row transfer line HTRL can be effectively reduced.

In some embodiments of the present disclosure, the first row transfer line section HTRL1 and the third row transfer line section HTRL3 respectively overlap with the driving power line VDDL. In other words, the first row transfer line section HTRL1 can be arranged in parallel with one driving power line VDDL (located in different film layers and extending along the same direction), and an overlapping part of orthographic projections of the first row transfer line section HTRL1 and the driving power line VDDL on the base substrate BP can extend along the second direction DV. The third row transfer line section HTRL3 can be arranged in parallel with one driving power line VDDL (located in different film layers and extending along the same direction), and an overlapping part of orthographic projections of the third row transfer line section HTRL3 and the driving power line VDDL on the base substrate BP can extend along the second direction DV. In this way, the driving power line VDDL can provide a certain signal shielding effect for the row transfer line HTRL, reducing the crosstalk of internal signals of the display panel to the row transfer line HTRL.

In some embodiments, the width of each row transfer line HTRL can be determined according to needs, so as to allow the load of each row line HL to be close as far as possible and to improve the uniformity of the display panel. In this way, the widths of any two row transfer lines HTRL can be the same or different.

In some embodiments of the present disclosure, as shown in FIGS. 2 to 5, a column transfer line VTRL can include a first column transfer line section VTRL1, a second column transfer line section VTRL2, and a third column transfer line section VTRL3 connected in sequence. In some embodiments, the first column transfer line section VTRL1 and the third column transfer line section VTRL3 extend along the first direction DH, and the second column transfer line section VTRL2 extends along the second direction DV. The column transfer line VTRL is electrically connected to the corresponding first column line section VL1 through the first column transfer line section VTRL1, and the column transfer line VTRL is electrically connected to the corresponding second column line section VL2 through the third column transfer line section VTRL3. The second column transfer line section VTRL2 can be arranged on a side of the holing area CC to which the first preset direction DH1 directs, or a side of the holing area CC to which the second preset direction DH2 directs.

In some embodiments, the holing area CC includes a column central axis Vaxis that extends along the second direction DV, and the column central axis Vaxis passes through the geometric center of the holing area CC. In some embodiments, the second column transfer line section VTRL2 connected with the row line HL that is located on a side of the column central axis Vaxis to which the first preset direction DH1 directs is located on the side of the holing area CC to which the first preset direction DH1 directs. The second column transfer line section VTRL2 connected with the row line HL that is located on a side of the column central axis Vaxis to which the second preset direction DH2 directs is located on the side of the holing area CC to which the second preset direction DH2 directs.

In some embodiments, for the second column transfer line sections VTRL2 connected to two adjacent first column line sections VL1, the second column transfer line section VTRL2 connected to the first column line section VL1 that is located away from the column central axis Vaxis is arranged far away from the holing area CC. In other words, on the same side of the column central axis Vaxis, the farther a distance between the first column line section VL1 and the column central axis Vaxis, the farther a distance from the second column transfer line section VTRL2 connected to the first column line section VL1 to the holing area CC. In this way, the length of each second column transfer line section VTRL2 will be close to each other, the signal difference between the column lines VL can be reduced, and thus facilitating the debugging of the display panel. In some embodiments, the column line VTRL can also be arranged in other ways. For example, for the second column transfer line sections VTRL2 connected with two adjacent first column line sections VL1, the second column transfer line section VTRL2 connected with the first column line section VL1 that is located away from the column central axis Vaxis is arranged close to the holing area CC.

In some embodiments of the present disclosure, the column line VL includes the driving power line VDDL. Some of the driving power lines VDDL are separated by the holing area CC into corresponding first driving-power-line section VDDL1 and second driving-power-line section VDDL2. The first driving-power-line section VDDL1 is located on a side of the holing area CC away from the binding area B1, and the second driving-power-line section VDDL2 is located on a side of the holing area CC close to the binding area B1. That is, the first driving-power-line section VDDL1 and the second driving-power-line section VDDL2 corresponding thereto are located on both sides of the holing area CC, respectively. In some embodiments, the first driving-power-line section VDDL1 is electrically connected to the second driving-power-line section VDDL2 corresponding thereto through the column transfer line VTRL. In some embodiments of the present disclosure, other conductive layers of the driving circuit layer can be provided with conductive structures electrically connected to the driving power line VDDL, for example, the second electrode plate of the storage capacitor. The conductive structures arranged in the same row can be connected to each other, for example, the second electrode plate of the storage capacitor of adjacent pixel driving circuits in the same row can be connected to each other. In this way, the driving power voltage VDD can have a grid signal path. In this case, the first driving-power-line section VDDL1 and the second driving-power-line section VDDL2 can be electrically connected to each other without using the column transfer line VTRL. Instead, the driving power voltage VDD can be obtained by connecting to the grid signal path of the driving power voltage VDD. As a result, the number of the column transfer line VTRL and the wiring space for the column transfer line VTRL can be reduced.

In some embodiments of the present disclosure, the column line VL includes the data line DataL. In some embodiments, some of the data lines DataL are separated by the holing area CC into corresponding first data line section DataL1 and second data line section DataL2. The first data line section DataL1 is located on a side of the holing area CC away from the binding area B1, and the second data line section DataL2 is located on a side of the holing area CC close to the binding area B1. That is, the first data line section DataL1 and the second data line section DataL2 corresponding thereto are located on both sides of the holing area CC, respectively. The corresponding first data line section DataL1 and second data line section DataL2 are electrically connected to each other through the column transfer line VTRL corresponding thereto.

In some embodiments, as shown in FIG. 1, the column line VL includes the driving power line VDDL and the data line DataL. In some embodiments, for the driving power line VDDL separated by the holing area CC, the first driving-power-line section VDDL1 and the second driving-power-line section VDDL2 are not electrically connected to each other through the column transfer line VTRL located in the display area AA, nor through the bypass line located in the enclosing area C1. As shown in FIGS. 2 to 4, for the data line DataL separated by the holing area CC, the first data line section DataL1 and the second data line section DataL2 corresponding thereto are electrically connected to each other through the column transfer line VTRL located in the display area AA. In some embodiments, for the second column transfer line sections VTRL2 connected with two adjacent first data line sections DataL1, the second column transfer line section VTRL2 connected with the first data line section DataL1 that is located away from the column central axis Vaxis is arranged away from the holing area CC.

In some embodiments of the present disclosure, as shown in FIGS. 3 and 5, an end of the first column transfer line section VTRL1 away from the second column transfer line section VTRL2 overlaps with the first column line section VL1 corresponding thereto, and is electrically connected with the first column line section VL1. An end of the third column transfer line section VTRL3 away from the second column transfer line section VTRL2 overlaps with the second column line section VL2 corresponding thereto, and is electrically connected with the second column line section VL2. In other words, the end of the first column transfer line section VTRL1 is electrically connected to the first column line section VL1 corresponding thereto through a via hole, and the end of the third column transfer line section VTRL3 is electrically connected to the second column line section VL2 corresponding thereto through a via hole. In this way, the length difference between different column transfer lines VTRL can be reduced, thereby reducing the impedance difference of the column lines VL, and improving the signal uniformity on both sides of the holing area CC. In some embodiments, the lengths of the first column transfer line sections VTRL1 are basically the same.

In some embodiments of the present disclosure, as shown in FIGS. 2 and 4, the column transfer line VTRL includes two portions of column transfer lines respectively located on both sides of the column central axis Vaxis. The ends of the column transfer lines VTRL located on the same side of the column central axis Vaxis are arranged in a straight line along the second direction DV. In other words, on the same side of the column central axis Vaxis, ends of the first column transfer line sections VTRL1 and ends of the third column transfer line sections VTRL3 are arranged in a straight line along the second direction DV. The first column transfer line section VTRL1 can be electrically connected to the first column line section VL1 corresponding thereto through a via hole located at its end or non-end. The third column transfer line section VTRL3 can be electrically connected to the second column line section VL2 corresponding thereto through a via hole located at its end or non-end. In this way, it can ensure that the impact of the column transfer line VTRL on the visual effect around the holing area CC is more uniform.

In some embodiments of the present disclosure, the second column transfer line section VTRL2 and the driving power line VDDL are arranged in overlapped manner. In other words, the second column transfer line section VTRL2 and the driving power line VDDL extend along the second direction DV, and their orthographic projections on the base substrate BP extends along the second direction DV. In this way, the driving power line VDDL can provide signal shielding for the driving data ‘Data’ loaded on the second column transfer line section VTRL2, improving the stability of the driving data.

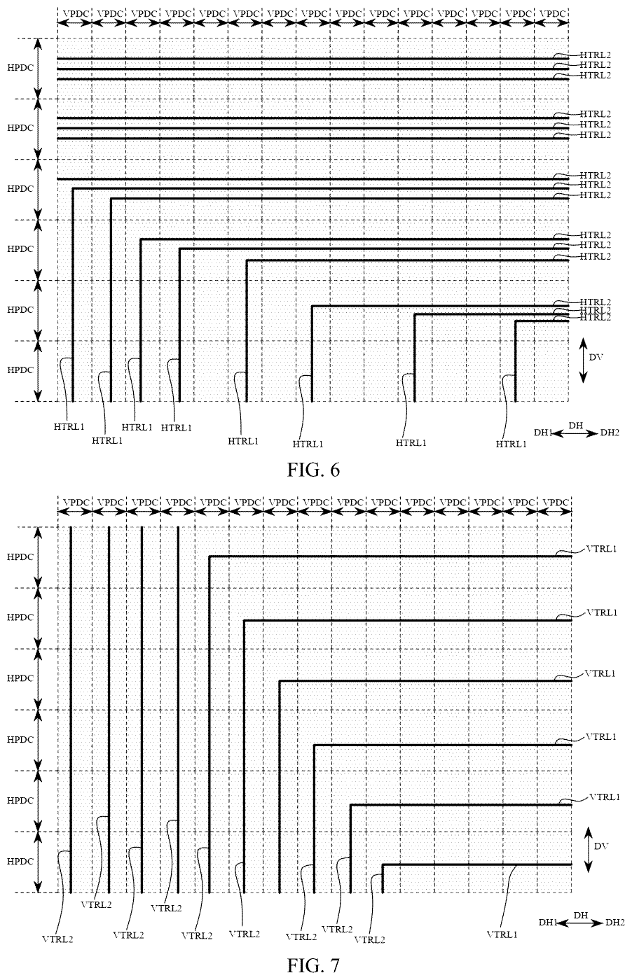

As shown in FIGS. 6 and 7, the display area AA is provided with pixel driving circuits arranged in an array. The pixel driving circuits are arranged in multiple rows of pixel driving circuits HPDC and multiple columns of pixel driving circuits VPDC. In some embodiments, any row of pixel driving circuits HPDC includes pixel driving circuits arranged along the first direction in sequence, and any column of pixel driving circuits VPDC includes pixel driving circuits arranged along the second direction in sequence.

In some embodiments of the present disclosure, for the second row transfer line sections HTRL2 of various row transfer lines HTRL, the second row transfer line sections HTRL2 located on the same side of the row central axis Haxis are divided into multiple groups of second row transfer line sections, and each group of second row transfer line sections includes multiple second row transfer line sections HTRL2 adjacent to each other. For example, each group of second row transfer line sections includes 2-4 adjacent second row transfer line sections HTRL2. Each group of second row transfer line sections overlaps with the same row of pixel driving circuits HPDC, and adjacent groups of second row transfer line sections respectively overlap with two adjacent rows of pixel driving circuits HPDC. For example, as shown in FIG. 6, each group of second row transfer line sections HTRL2 includes three second row transfer line sections HTRL2.

As shown in FIGS. 2 and 3, in some embodiments of the present disclosure, the first row transfer line H1TRL includes a first row transfer line section HTRL1, a second row transfer line section HTRL2, and a third row transfer line section HTRL3. In some embodiments, positions of the first row transfer line section HTRL1 and the third row transfer line section HTRL3 can be determined based on positions of ends of the first row line section HL1 and the second row line section HL2 corresponding to the first row transfer line H1TRL which are close to the holing area CC, and thus determining the length of the second row transfer line section HTRL2. In some embodiments, an end of the first row line section HL1 close to the holing area CC can be connected to an end of the first row transfer line section HTRL1 close to the holing area CC, and an end of the second row line section HL2 close to the holing area CC can be connected to an end of the second row transfer line section HTRL2 close to the holing area CC. In some embodiments, the first row transfer line section HTRL1 and the third row transfer line section HTRL3 extend along the second direction DV and overlap with the column of pixel driving circuits VPDC. At the wiring of each column of pixel driving circuits VPDC, it is not provided with multiple first row transfer line sections HTRL1 extending in parallel or multiple third row transfer line sections HTRL3 extending in parallel. In other words, on the same side of the row central axis Haxis, the wiring area of each column of pixel driving circuits VPDC only overlaps with one first row transfer line section HTRL1 or one third row transfer line section HTRL3. In some embodiments, the first row transfer line section HTRL1 and the third row transfer line section HTRL3 overlap with the driving power line VDDL in the column of pixel driving circuits VPDC. It can be understood that in the wiring space of the column of pixel driving circuits VPDC, two first row transfer line sections HTRL1 or two third row transfer line sections HTRL3 can be arranged on both sides of the row central axis Haxis.

According to different ends of first row line section HL1 and the second row line section HL2, two adjacent first row transfer line sections HTRL1 or two adjacent third row transfer line sections HTRL3 can be spaced by one or more columns of pixel driving circuits VPDC, or the column of pixel driving circuits VPDC can be not provided between two adjacent first row transfer line sections HTRL1 or two adjacent third row transfer line sections HTRL3.

In some embodiments, on the same side of the row central axis Haxis, each second row transfer line section HTRL2 is numbered sequentially along a direction away from the row central axis Haxis. The second row transfer line section HTRL2 closest to the row central axis Haxis is numbered as the 1^{st} second row transfer line section HTRL2, and the rest are so on. The first row transfer line section HTRL1 to which the i^{th} second row transfer line section HTRL2 is connected is noted as HTRL1 (i), and the third row transfer line section HTRL3 to which the i^{th} second row transfer line section HTRL2 is connected is noted as HTRL3(i). In some embodiments, HTRL1(1) and HTRL1(2) are spaced apart by five columns of pixel driving circuits VPDC with the first row transfer line section HTRL1 being not provided in these columns of pixel driving circuits VPDC; HTRL1(2) and HTRL1(3) are spaced apart by three columns of pixel driving circuits VPDC with the first row transfer line section HTRL1 being not provided in these columns of pixel driving circuits VPDC, and HTRL1(3) and HTRL1(4) are spaced apart by three columns of pixel driving circuits VPDC with the first row transfer line section HTRL1 being not provided in these columns of pixel driving circuits VPDC; HTRL1(4) and HTRL1(5), HTRL1(5) and HTRL1(6), HTRL1(6) and HTRL1(7), HTRL1(7) and HTRL1(8), and HTRL1(8) and HTRL1(9) are spaced apart by one column of pixel driving circuits VPDC with the first row transfer line section HTRL1 being not provided in this column of pixel driving circuits VPDC. Accordingly, in some embodiments, adjacent third row transfer line sections HTRL3 can present the same pattern, for example, the third row transfer line sections HTRL3 and the first row transfer line sections HTRL1 are symmetrical along the column central axis Vaxis.

As shown in FIGS. 4 and 5, in some embodiments of the present disclosure, the second row transfer line H2TRL includes a fourth row transfer line section HTRL4, a first row transfer line section HTRL1, a second row transfer line section HTRL2, a third row transfer line section HTRL3, and a fifth row transfer line section HTRL5, which are connected in sequence. The first row transfer line sections HTRL1 of these row transfer lines HTRL can be arranged in one-by-one correspondence with adjacent columns of pixel driving circuits VPDC. Correspondingly, the third row transfer line sections HTRL3 of these row transfer lines HTRL can be arranged in one-by-one correspondence with adjacent columns of pixel driving circuits VPDC.

In some embodiments, as shown in FIG. 7, two first column transfer line sections VTRL1 adjacent along the second direction DV are respectively located in two adjacent rows of pixel driving circuits HPDC, two third column transfer line sections VTRL3 adjacent along the second direction DV are respectively located in two adjacent rows of pixel driving circuits HPDC, and two second column transfer line sections VTRL2 adjacent along the first direction DH are respectively located in two adjacent columns of pixel driving circuits VPDC. In this way, the wiring space for the column transfer lines VTRL can be reduced.

In some embodiments, the width of each column transfer line VTRL can be determined according to needs, so as to allow the load of each column line VL to be close as far as possible and to improve the uniformity of the display panel. In this way, the widths of any two column transfer lines VTRL can be the same or different.

Further introductions and explanations of the structure, principle, and effect of the display panel of the present disclosure will be provided in the following, with reference to examples. It can be understood that the structures provided in embodiments are only examples of the present disclosure, and the display panel of the present disclosure can also be embodied as other structures.

As shown in FIG. 1, the display panel is provided with a holing area CC near a top corner of the display area AA. The holing area CC includes a hole C2 and an enclosing area C1 surrounding the hole C2. The display area AA has a transfer area A1 around the holing area CC. The transfer area A1 is used for arranging the transfer line TRL. The display area AA further includes a non-transfer area A2 surrounding the transfer area A1.

Regarding a film structure, as shown in FIG. 16, the display panel includes a base substrate BP, a driving circuit layer F100, and a pixel layer F200 arranged in stacked manner in sequence. In some embodiments, the driving circuit layer F100 includes a buffer material layer Buff, a semiconductor layer Poly, a first gate insulation layer GI1, a first gate layer G1, a second gate insulation layer GI2, a second gate layer G2, an interlayer dielectric layer ILD, a first source-drain metal layer SD1, a first planarization layer PLN1, a second source-drain metal layer SD2, and a second planarization layer PLN2, which are arranged in stacked manner in sequence. The pixel layer is provided with OLED as the sub pixel.

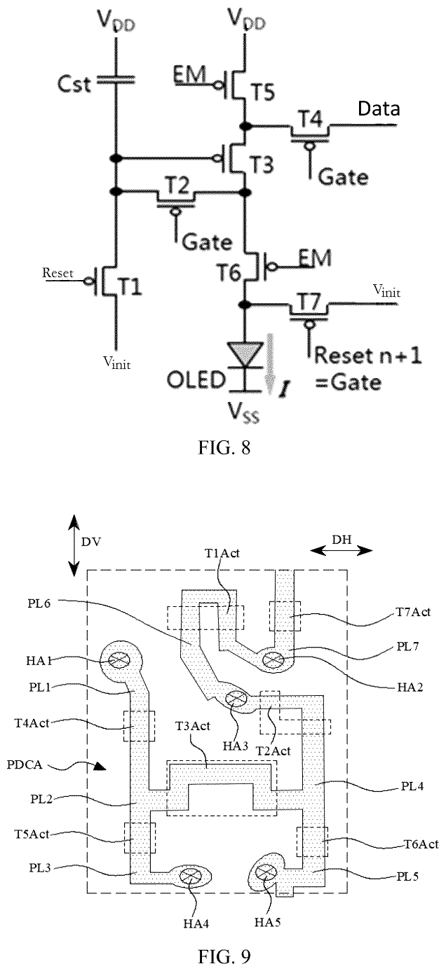

In the display panel, the display area AA is provided with pixel driving circuits arranged in an array. As shown in FIG. 8, the pixel driving circuit adopts a 7TIC architecture. The pixel driving circuit includes a capacitor reset transistor T1, a threshold compensation transistor T2, a driving transistor T3, a data writing transistor T4, a first light-emitting control transistor T5, a second light-emitting control transistor T6, an electrode reset transistor T7, and a storage capacitor Cst. As shown in FIGS. 8 to 15, a source of the driving transistor T3, a drain of the first light-emitting control transistor T5, and a drain of the data writing transistor T4 are electrically connected to each other. A drain of the driving transistor T3, a source of the threshold compensation transistor T2, and a source of the second light-emitting control transistor T6 are electrically connected to each other. A gate T3G of the driving transistor T3, a first electrode plate CP1 of the storage capacitor, a drain of the threshold compensation transistor T2, and a drain of the capacitor reset transistor T1 are electrically connected to each other. The driving transistor T3 is configured to output a driving current to control the brightness of the OLED under the control of the voltage on the gate T3G of the driving transistor T3. The source of the data writing transistor T4 is configured to load driving data, and the gate T4G of the data writing transistor T4 is configured to load a scanning signal Gate. The data writing transistor T4 is configured to output the driving data to the drain of the data writing transistor T4 in response to the scanning signal Gate. The gate T2G of the threshold compensation transistor T2 is configured to load a scanning signal Gate and is turned on in response to the scanning signal Gate, to compensate for the threshold voltage of the driving transistor T3. The gate T1G of the capacitor reset transistor T1 is configured to load a reset control signal Reset, the source of the capacitor reset transistor T1 is configured to load an initialization voltage Vinit, and the capacitor reset transistor T1 is configured to load the initialization voltage Vinit to the drain of the capacitor reset transistor T1 in response to the reset control signal Reset. The source of the electrode reset transistor T7 is configured to load an initialization voltage Vinit, the gate T7G of electrode reset transistor T7 is configured to load a reset control signal Reset, and the electrode reset transistor T7 is configured to load the initialization voltage Vinit to the drain of electrode reset transistor T7 in response to the reset control signal Reset. The source of the first light-emitting control transistor T5 is configured to load a driving power voltage VDD, the gate T5G of the first light-emitting control transistor T5 is configured to load an enabling signal EM, and the gate T6G of the second light-emitting control transistor T6 is configured to load the enabling signal EM. The first light-emitting control transistor T5 and the second light-emitting control transistor T6 are turned on in response to the enabling signal EM. The second electrode plate CP2 of the storage capacitor is configured to load the driving power voltage VDD. The pixel electrode of OLED can be electrically connected to the drain of the second light-emitting control transistor T6, and the common electrode can be loaded with a common power voltage VSS. In the pixel driving circuits distributed in an array, the reset control signal Reset loaded by the capacitor reset transistor T1 of the pixel driving circuit in the previous row is the same (at a high level or at a low level at the same time) as the scanning signal Gate loaded by the pixel driving circuit in the next row. The scanning signal Gate loaded by the pixel driving circuit in the previous row is the same as the reset control signal Reset loaded by the electrode reset transistor T7 of the pixel driving circuit in the next row. In the present disclosure, the reset control signal Reset loaded by the capacitor reset transistor T1 of the pixel driving circuit can be used as the reset control signal Reset of the pixel driving circuit. That is, the reset control line RL connected to the capacitor reset transistor T1 can be used as the reset control line RL connected to the row of pixel driving circuits. In this way, the electrode reset transistor T7 of the pixel driving circuit in the previous row can be connected to the reset control line RL of the pixel driving circuit in the next row.

In the present disclosure, an area where the transistors of a pixel driving circuit are arranged can be defined as a pixel driving area PDCA for the pixel driving circuit. Most of the transistors of the pixel driving circuit are arranged in the corresponding pixel driving area PDCA. In some embodiments, as shown in FIGS. 9 to 15, the pixel driving area PDCA can be defined as a rectangular area. The capacitor reset transistor T1 to the second light-emitting control transistor T6 of the pixel driving circuit are arranged in the corresponding pixel driving area PDCA, and the electrode reset transistor T7 of the pixel driving circuit is arranged in the corresponding pixel driving area PDCA for the pixel driving circuit in the next row. According to such arrangement, the pixel driving area PDCA includes seven transistors, namely the capacitor reset transistor T1 to the electrode reset transistor T7. The capacitor reset transistor T1 to the second light-emitting control transistor T6 belong to the pixel driving circuit corresponding to the pixel driving area PDCA, and the electrode reset transistor T7 belongs to the pixel driving circuit in the previous row.

In the display panel, the material of the active layer 200 can be polycrystalline silicon, the conductivity of which at different positions can be changed through doping and other processes, thereby forming multiple channel regions and conductive sections. In some embodiments, as shown in FIG. 9, in any one of the pixel driving circuits, the active layer 200 can form a channel region T1Act of the capacitor reset transistor T1, a channel region T2Act of the threshold compensation transistor T2, a channel region T3 Act of the driving transistor T3, a channel region T4Act of the data writing transistor T4, a channel region T5Act of the first light-emitting control transistor T5, a channel region T6Act of the second light-emitting control transistor T6, and a channel region T7Act of the electrode reset transistor T7, as well as forming a first conductive section PL1, a second conductive section PL2, a third conductive section PL3, a fourth conductive section PL4, a fifth conductive section PL5, a sixth conductive section PL6, and a seventh conductive section PL7. In some embodiments, the first conductive section PL1 is connected to one end of the channel region T4Act of the data writing transistor T4, so as to serve as the source of the data writing transistor T4, and the first conductive section PL1 is provided with a first bottom via-hole region HA1 for electrically connecting with the data line DataL. The second conductive section PL2 is connected to the other end of the channel region T4Act of the transistor T4, and is connected to one end of the channel region T3 Act of the driving transistor T3 and one end of the channel region T5Act of the first light-emitting control transistor T5, so that the drain of the data writing transistor T4, the source of the driving transistor T3, and the drain of the first light-emitting control transistor T5 are electrically connected to each other. The third conductive section PL3 is connected to the other end of the first light-emitting control transistor T5, so as to serve as the source of the first light-emitting control transistor T5, and the third conductive section PL3 is provided with a fourth bottom via-hole region HA4 for electrically connecting with the driving power line VDDL. The fourth conductive section PL4 is electrically connected to the other end of the channel region T3Act of the driving transistor T3, one end of the channel region T2Act of the threshold compensation transistor T2, and one end of the channel region T6Act of the second light-emitting control transistor T6, so that the drain of the driving transistor T3, the source of the threshold compensation transistor T2, and the source of the second light-emitting control transistor T6 are electrically connected. The fifth conductive section PL5 is electrically connected to one end of the channel region T7Act of the electrode reset transistor T7, and is provided with a fifth bottom via-hole region HA5 for electrically connecting with the first source-drain metal layer SD1.

The sixth conductive section PL6 is electrically connected to the other end of the channel region T2Act of the threshold compensation transistor T2 and one end of the channel region T1Act of the capacitor reset transistor T1, for electrically connecting the drain of the capacitor reset transistor T1 to the drain of the threshold compensation transistor T2. The sixth conductive section PL6 is provided with a third bottom via-hole region HA3 for electrically connecting with the first source-drain metal layer SD1. The seventh conductive section PL7 is electrically connected to the other end of the channel region T1Act of the capacitor reset transistor T1 of the pixel driving circuit, and electrically connected to the other end of the channel region T7Act of the electrode reset transistor T7 of the pixel driving circuit in the previous row. The seventh conductive section PL7 is provided with a second bottom via-hole region HA2 for electrically connecting with the first source-drain metal layer SD1.

As shown in FIG. 9, the channel region T1Act of the capacitor reset transistor T1 includes two sub channel regions electrically connected to each other, so that the capacitor reset transistor T1 includes two sub transistors in series. The channel region T2Act of the threshold compensation transistor T2 includes two sub channel regions electrically connected to each other, so that the threshold compensation transistor T2 includes two sub transistors in series. In this way, the leakage of the first electrode plate CP1 of the storage capacitor can be reduced, and the voltage retention ability of the pixel driving circuit can be improved.

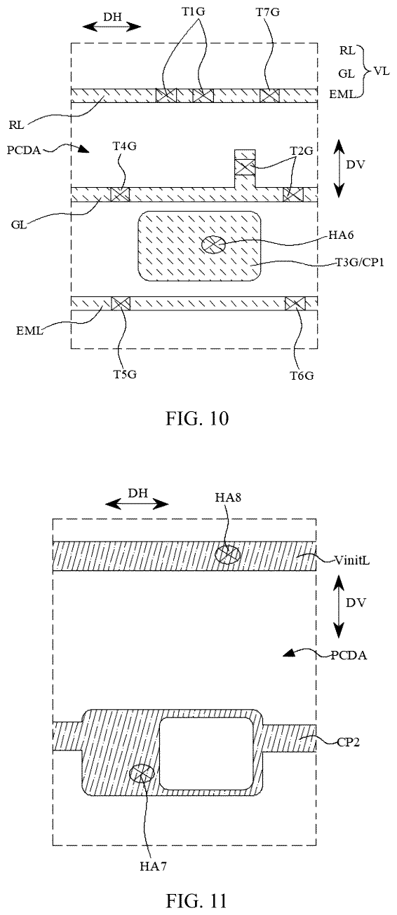

As shown in FIG. 10, the first gate layer is provided with a scanning line GL extending along the first direction DH, a reset control line RL, and an enabling line EML, as well as a first electrode plate CP1 of the storage capacitor. The first electrode plate CP1 of the storage capacitor overlaps with the channel region T3Act of the driving transistor T3, to be multiplexed as the gate T3G of the driving transistor T3. In some embodiments, the first electrode plate CP1 of the storage capacitor is provided with a sixth bottom via-hole region HA6 for electrically connecting with the first source-drain metal layer SD1.

An overlapping part between the reset control line RL and the channel region T1Act of the capacitor reset transistor T1 can serve as the gate T1G of the capacitor reset transistor T1. In some embodiments, the reset control line RL has two regions that respectively overlap with the two sub channel regions of the channel region T1Act of the capacitor reset transistor T1, serving as the gates of the two sub transistors of the capacitor reset transistor T1, respectively. An overlapping part between the reset control line RL and the channel region T7Act of the electrode reset transistor T7 serves as the gate T7G of the electrode reset transistor T7. An overlapping part between the scanning line GL and the channel region T4Act of the data writing transistor T4 serves as the gate T4G of the data writing transistor T4. An overlapping part between the scanning line GL and the channel region T2Act of the threshold compensation transistor T2 serves as the gate T2G of the threshold compensation transistor T2. As shown in FIG. 10, the scanning line GL can have a branch part, and the branch part overlaps with one sub channel region of the channel region T2Act of the threshold compensation transistor T2, so as to be multiplexed as the gate of one sub transistor of the threshold compensation transistor T2. An overlapping part between the enabling line EML and the channel region T5Act of the first light-emitting control transistor T5 is multiplexed as the gate T5G of the first light-emitting control transistor T5. An overlapping part between the enabling line EML and the channel region T6Act of the second light-emitting control transistor T6 is multiplexed as the gate T6G of the second light-emitting control transistor T6. As shown in FIG. 10, the gate T1G of the capacitor reset transistor T1 of the pixel driving circuit in the current row and the gate T7G of the electrode reset transistor T7 of the pixel driving circuit in the next row are arranged in a straight line along the first direction DH. The gate T4G of the data writing transistor T4 and the gate of one sub transistor of the threshold compensation transistor T2 are arranged in a straight line along the first direction DH. The gate T5G of the first light-emitting control transistor T5 and the gate T6G of the second light-emitting control transistor T6 are arranged in a straight line along the first direction DH.

As shown in FIG. 11, the second gate layer includes an initialization line VinitL extending along the first direction DH, and the initialization line VinitL is provided with an eighth bottom via-hole region HA8 for electrically connecting with the first source-drain metal layer SD1. The second gate layer is further provided with a second electrode plate CP2 of the storage capacitor, and the second electrode plate CP2 of the storage capacitor is provided with a gap that exposes the sixth bottom via-hole region HA6, to enable the sixth bottom via-hole region HA6 to be electrically connected to the first source-drain metal layer SD1. The second electrode plate CP2 of the storage capacitor overlaps with the first electrode plate CP1 of the storage capacitor to form the storage capacitor Cst. In some embodiments, the second electrode plate CP2 of the storage capacitor is provided with a seventh bottom via-hole region HA7 for electrically connecting with the driving power line VDDL. The second electrode plate CP2 of the storage capacitor further has a connection line extending along the first direction DH, so that the second electrode plate CP2 of the storage capacitor of adjacent pixel driving circuits in the same row can be electrically connected to each other. In this way, the second electrode plate CP2 of the storage capacitor connected sequentially along the first direction DH can serve as a VDD signal channel for the driving power voltage in the first direction DH, which is electrically connected to the driving power line VDDL along the second direction DV. In this way, the signal channels for the driving power voltage VDD can be gridded.

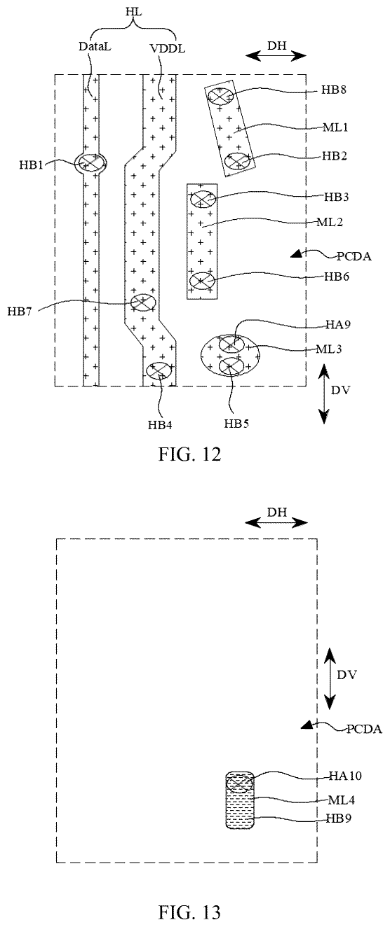

As shown in FIGS. 12 and 13, the first source-drain metal layer SD1 includes a data line DataL and a driving power line VDDL, which extend along the second direction DV, and the first source-drain metal layer SD1 also includes a first conductive structure ML1, a second conductive structure ML2, and a third conductive structure ML3. The second source-drain metal layer SD2 is provided with a fourth conductive structure ML4. In some embodiments, the data line DataL has a first top via-hole region HB1, which overlaps with the first bottom via-hole region HA1 and is connected to the first bottom via-hole region HA1 through a via hole, so that the data line DataL can be electrically connected to the source of the data writing transistor T4. The driving power line VDDL has a fourth via-hole region HB4 and a seventh via-hole region HB7. The fourth top via-hole region HB4 overlaps with the fourth bottom via-hole region HA4 and is connected to the fourth bottom via-hole region HA4 through a via hole, so that the driving power line VDDL can be electrically connected to the source of the first light-emitting control transistor T5. The seventh top via-hole region HB7 overlaps with the seventh bottom via-hole region HA7 and is connected to the seventh bottom via-hole region HA7 through a via hole, so that the driving power line VDDL can be electrically connected to the second electrode plate CP2 of the storage capacitor. The first conductive structure ML1 has a second top via-hole region HB2 and an eighth top via-hole region HB8. The second top via-hole region HB2 overlaps with the second bottom via-hole region HA2 and is connected to the second bottom via-hole region HA2 through a via hole, and the eighth top via-hole region HB8 overlaps with the eighth bottom via-hole region HA8 and is connected to the eighth bottom via-hole region HA8 through a via hole, so that the initialization line VinitL can be electrically connected to the source of the capacitor reset transistor T1 and the source of the electrode reset transistor T7 through the first conductive structure ML1. The second conductive structure ML2 has a third top via-hole region HB3 and a sixth top via-hole region HB6. The third top via-hole region HB3 overlaps with the third bottom via-hole region HA3 and is connected to the third bottom via-hole region HA3 through a via hole, and the sixth top via-hole region HB6 overlaps with the sixth bottom via-hole region HA6 and is connected to the sixth bottom via-hole region HA6 through a via hole, so that the drain of the threshold compensation transistor T2 can be electrically connected to the first electrode plate CP1 of the storage capacitor through the second conductive structure ML2. The third conductive structure ML3 has a fifth top via-hole region HB5 and a ninth bottom via-hole region HA9. The fourth conductive structure ML4 is provided with a ninth top via-hole region HB9 and a tenth bottom via-hole region HA10. The fifth top via-hole region HB5 overlaps with the fifth bottom via-hole region HA5 and is connected to the fifth bottom via-hole region HA5 through a via hole, the ninth top via-hole region HB9 overlaps with the ninth bottom via-hole region HA9 and is connected to the ninth bottom via-hole region HA9 through a via hole, and the tenth bottom via-hole region HA10 is configured to be electrically connected with the pixel electrode of the OLED. In this way, the OLED can be electrically connected to the drain of the second light-emitting control transistor T6 through the fourth conductive structure ML4 and the third conductive structure ML3.

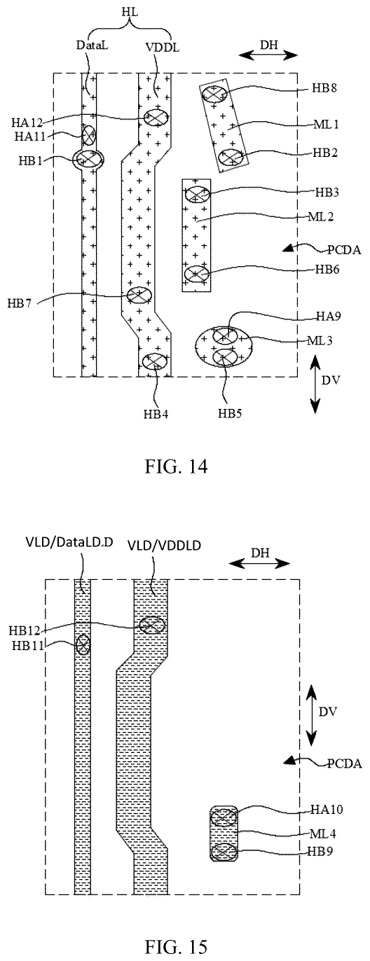

FIGS. 14 and 15 are schematic diagrams of structures of the first source-drain metal layer SD1 and the second source-drain metal layer SD2 in the non-transfer area A2. In some embodiments, in the non-transfer area A2, the data line DataL is further provided with an eleventh bottom via-hole region HA11, and the driving power line VDDL is further provided with a twelfth bottom via-hole region HA12. The second source-drain metal layer SD2 is further provided with a resistance reduction structure DataLD for data line and a resistance reduction structure VDDLD for driving power line, which extend along the second direction DV. In some embodiments, the resistance reduction structure DataLD for data line is provided with an eleventh top via-hole region HB11, which overlaps with the eleventh bottom via-hole region HA11 and is connected to the eleventh bottom via-hole region HA11 through a via hole, so that the resistance reduction structure DataLD for data line is parallel to the data line DataL corresponding thereto, thereby reducing the impedance of the data line DataL. The resistance reduction structure VDDLD for driving power line is provided with a twelfth top via-hole region HB12. The twelfth top via-hole region HB12 overlaps with the twelfth bottom via-hole region HA12 and is connected to the twelfth bottom via-hole region HA12 through a via hole, so that the resistance reduction structure VDDLD for driving power line is parallel to the driving power line VDDL corresponding thereto, thereby reducing the impedance of the driving power line VDDL.

FIG. 17 shows a schematic diagram of a local structure of the first source-drain metal layer SD1, the second source-drain metal layer SD2, and some gate lines in the transfer area A1. FIG. 18 shows a schematic diagram of a local structure of the first source-drain metal layer SD1, the second source-drain metal layer SD2, the pixel electrode layer, and some gate lines in the transfer area A1. In FIG. 18, the pixel electrode R of the red sub pixel, the pixel electrode G of the green sub pixel, and the pixel electrode B of the blue sub pixel are distributed in the display area.

As shown in FIGS. 17 and 18, in the display panel, on a side close to the enclosing area C1, the first source-drain metal layer SD1 is provided with a scanning transfer structure GD. The scanning transfer structure GD is connected to the scanning line GL (such as the first scanning line section GL1 or the second scanning line section GL2) in the previous row of pixel driving circuits HPDC through a via hole, and is connected to the reset control line RL (the first reset control line section RL1 or the second reset control line section RL2) in the next row of pixel driving circuits HPDC through a via hole, and also is connected to the row transfer line HTRL through a via hole, so that the scanning line GL in the previous row of pixel driving circuits HPDC can be electrically connected to the reset control line RL (serving as the reset control line RL corresponding to the scanning line GL in the previous row of pixel driving circuits HPDC) in the next row of pixel driving circuits HPDC through the row transfer line HTRL.

In some embodiments, the pixel driving circuit closest to the holing area CC in the row of pixel driving circuits HPDC being separated can be defined as the innermost pixel driving circuit. An auxiliary area can be arranged on a side of the innermost pixel driving circuit close to the enclosing area C1, and the scanning transfer structure GD is arranged in the auxiliary area. The first scanning line section GL1 or the second scanning line section GL2 in the row of pixel driving circuits HPDC needs to extend along the first direction DH to the auxiliary area, so as to be electrically connected to the scanning transfer structure GD. Correspondingly, the reset control line RL in the next row of pixel driving circuits HPDC also needs to extend to the auxiliary area, so as to be electrically connected to the scanning transfer structure GD.

As shown in FIG. 17, for the row transfer line HTRL, the lines along the second direction DV can overlap with the driving power line VDDL, to shield signals such as the driving data ‘Data’ by means of the driving power line VDDL, so as to reduce the crosstalk received by the row transfer line HTRL. In some embodiments, for the row transfer line HTRL, the lines along the second direction DV may not overlap with the data line DataL.

In some embodiments, the first source-drain metal layer SD1 can further be provided with an enabling transfer structure EMD in the auxiliary area, which is electrically connected to the enabling line EML through a via hole. In the enclosing area C1, an enabling bypass line (not shown in FIGS. 17 and 18) can be provided. The enabling bypass line can be arranged in one or two layers from the first gate layer and the second gate layer, so that the first enabling line section EML1 can be electrically connected to the second enabling line section EML2. In some embodiments, the enabling bypass line can be electrically connected to the enabling transfer structure EMD through a via hole. In some embodiments of the present disclosure, the enabling bypass line is alternately arranged in the first gate layer and the second gate layer.

In some embodiments, the enclosing area C1 is provided with a reference voltage bypass line VinitER surrounding the hole C2, and a connection part protruding towards the auxiliary area is arranged on the reference voltage bypass line VinitER. The connection part is electrically connected to the first initialization line section or the second initialization line section (not shown in FIGS. 17 and 18) through a via hole, so that each first initialization line section and each second initialization line section can be electrically connected through the reference voltage bypass line VinitER, thereby reducing the difference in the initialization voltage Vinit on both sides of the holing area CC and improving the uniformity of the display panel.

After considering the specification and practicing of the invention of the present disclosure, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are defined by appended claims.

1. A display panel comprising a holing area and a display area surrounding the holing area, wherein the display panel is provided with a row line extending along a first direction and a column line extending along a second direction, and the first direction intersects with the second direction;
wherein a portion of the row line is separated by the holing area into a first row line section and a second row line section corresponding to each other, and a portion of the column line is separated by the holing area into a first column line section and a second column line section corresponding to each other; and
wherein at least a portion of the first column line section is electrically connected to the second column line section corresponding thereto through a transfer line corresponding thereto located in the display area; and/or
at least a portion of the first row line section is electrically connected to the second row line section corresponding thereto through a transfer line corresponding thereto located in the display area.

2. The display panel according to claim 1, wherein the column line comprises a data line for loading driving data, and a portion of the data line is separated by the holing area into a first data line section and a second data line section corresponding to each other; and
wherein the first data line section is electrically connected to the second data line section corresponding thereto through a column transfer line corresponding thereto located in the display area.

3. The display panel according to claim 2, wherein the column transfer line comprises a first column transfer line section, a second column transfer line section, and a third column transfer line section that are connected in sequence, and
wherein the first column transfer line section is electrically connected to the first data line section, and the third column transfer line section is electrically connected to the second data line section.

4. The display panel according to claim 3, wherein the first column transfer line section and the third column transfer line section extend along the first direction, and the second column transfer line section extends along the second direction; and
wherein the holing area has a column central axis extending along the second direction, column transfer lines electrically connected with first data line sections that are located on one side of the column central axis are located on the same side of the column central axis.

5. The display panel according to claim 4, wherein the column transfer line comprises two portions of column transfer lines respectively located on both sides of the column central axis; and
wherein ends of the column transfer lines located on the same side of the column central axis are arranged in a straight line along the second direction.

6. The display panel according to claim 3, wherein an end of the first column transfer line section away from the second column transfer line section overlaps and is electrically connected with the first data line section corresponding thereto, and an end of the third column transfer line section away from the second column transfer line section overlaps and is electrically connected with the second data line section corresponding thereto.

7. (canceled)

8. The display panel according to claim 3, wherein the display area is provided with pixel driving circuits arranged in an array, and the pixel driving circuits are arranged in multiple rows of pixel driving circuits and multiple columns of pixel driving circuits; and
wherein two first column transfer line sections adjacent along the second direction are respectively located in two adjacent rows of pixel driving circuits,
two third column transfer line sections adjacent along the second direction are respectively located in two adjacent rows of pixel driving circuits, and
two second column transfer line sections adjacent along the first direction are respectively located in two adjacent columns of pixel driving circuits.

9. The display panel according to claim 1, wherein the row line comprises a scanning line for loading a scanning signal, and a portion of the scanning line is separated by the holing area into a first scanning line section and a second scanning line section corresponding to each other; and
wherein the first scanning line section is electrically connected to the second scanning line section corresponding thereto through a row transfer line corresponding thereto located in the display area.

10. The display panel according to claim 9, wherein at least a portion of the row transfer line is a first row transfer line, the first row transfer line comprises a first row transfer line section, a second row transfer line section, and a third row transfer line section that are connected in sequence, the first row transfer line section and the third row transfer line section extend along the second direction, and the second row transfer line section extends along the first direction; and
wherein the first row transfer line section is electrically connected to the first scanning line section corresponding thereto, and the third row transfer line section is electrically connected to the second scanning line section corresponding thereto.

11. The display panel according to claim 10, wherein the first row transfer line section of the first row transfer line is electrically connected to the first scanning line section corresponding thereto at an end of the first row transfer line section, and the third row transfer line section of the first row transfer line is electrically connected to the second scanning line section corresponding thereto at an end of the third row transfer line section.

12-14. (canceled)

15. The display panel according to claim 9, wherein the holing area has a row central axis extending along the first direction, and row transfer lines corresponding to first scanning line sections that are located on one side of the row central axis are located on the same side of the row central axis.

16. The display panel according to claim 10, wherein the row line further comprises a reset control line, the reset control line corresponds to the scanning line and is configured for loading a reset control signal, a signal loaded by the reset control line is consistent with a signal loaded by the scanning line corresponding thereto, and a portion of the reset control line is separated by the holing area into a first reset control line section and a second reset control line section corresponding to each other; and
wherein the first scanning line section and the first reset control line section corresponding thereto are arranged side by side, and are electrically connected to the same first row transfer line section; and
the second scanning line section and the second reset control line section corresponding thereto are arranged side by side, and are electrically connected to the same third row transfer line section.

17. The display panel according to claim 16, wherein the holing area comprises a hole and an enclosing area surrounding the hole;
the enclosing area is provided with scanning transfer structures respectively corresponding to the first scanning line section and the second scanning line section one by one;
the first scanning line section and the first reset control line section corresponding thereto are electrically connected to a scanning transfer structure corresponding thereto;
the second scanning line section and the second reset control line section corresponding thereto are electrically connected to a scanning transfer structure corresponding thereto.

18. The display panel according to claim 17, wherein the scanning line and the reset control line corresponding thereto are located on the same conductive layer, and the scanning line, the scanning transfer structure corresponding thereto, and the row transfer line corresponding thereto are located on different conductive layers; and
wherein the first scanning line section and the first reset control line section corresponding thereto are electrically connected to the scanning transfer structure corresponding thereto through via holes, and the second scanning line section and the second reset control line section corresponding thereto are electrically connected to the scanning transfer structure corresponding thereto through via holes; and
wherein the scanning transfer structure corresponding to the first scanning line section is electrically connected to the row transfer line corresponding to the first scanning line section through a via hole; and
the scanning transfer structure corresponding to the second scanning line section is electrically connected to the row transfer line corresponding to the second scanning line section through a via hole.

19. The display panel according to claim 1, wherein the holing area comprises a hole and an enclosing area surrounding the hole, and the row line comprises an enabling line for loading an enabling signal; and
wherein a portion of the enabling line is separated by the holing area into a first enabling line section and a second enabling line section corresponding to each other, and the first enabling line section is electrically connected to the second enabling line section corresponding thereto through an enabling bypass line corresponding thereto that is arranged in the enclosing area.

20. The display panel according to claim 19, wherein the display panel comprises a first gate layer and a second gate layer arranged in stacked manner, the first gate layer is provided with the enabling line and a first electrode plate of a storage capacitor, and the second gate layer is provided with a second electrode plate of the storage capacitor; and
wherein the enabling bypass line is arranged in the first gate layer and/or the second gate layer.

21. The display panel according to claim 1, wherein the holing area comprises a hole and an enclosing area surrounding the hole, the row line comprises an initialization line for loading an initialization voltage, and a portion of the initialization line is separated by the holing area into a first initialization line section and a second initialization line section corresponding to each other; and
wherein the enclosing area is provided with a reference voltage bypass line surrounding the hole, and the first initialization line section and the second initialization line section are electrically connected to the reference voltage bypass line.

22. The display panel according to claim 1, wherein the transfer line comprises a row transfer line and a column transfer line, the row transfer line is configured to electrically connect the first row line section with the second row line section corresponding thereto, the column transfer line is configured to electrically connect the first column line section with the second column line section corresponding thereto, and a wiring space for the row transfer line is located within a wiring space for the column transfer line.

23. The display panel according to claim 22, wherein, the row transfer line is arranged on both sides of the holing area along the second direction, and the column transfer line is arranged on both sides of the holing area along the first direction; and
wherein the column transfer line is connected to the column line corresponding thereto through a column transfer via hole, the row transfer line is connected to the row line through a row transfer via hole, and a distance between the column transfer via hole and the holing area is greater than a distance between the row transfer via hole and the holing area.

24-28. (canceled)

29. An electronic device comprising a display panel according to claim 1.
